(19) United States
(12) Patent Application Publication
(10) Pub. No.: US 2025/0311100 A1
(43) Pub. Date: Oct. 2, 2025

(54) PRINTED CIRCUIT BOARD

(71) Applicant: SAMSUNG ELECTRO-MECHANICS CO., LTD., Suwon-si (KR)

(72) Inventors: Sang Ho JEONG, Suwon-si (KR); Jong Eun PARK, Suwon-si (KR); Chang Hwa PARK, Suwon-si (KR); Hyun Hu LEE, Suwon-si (KR)

(73) Assignee: SAMSUNG ELECTRO-MECHANICS CO., LTD., Suwon-si (KR)

(21) Appl. No.: 19/025,151

(22) Filed: Jan. 16, 2025

(30) Foreign Application Priority Data
Mar. 28, 2024 (KR) 10-2024-0042594
May 16, 2024 (KR) 10-2024-0063660

(51) Int. Cl. H05K 1/11; H05K 3/22; H05K 3/40

(52) U.S. Cl. CPC H05K 1/111; H05K 1/115; H05K 3/22; H05K 3/4038; H05K 2201/09036

(57) ABSTRACT

A printed circuit board and a method of manufacturing the printed circuit board are provided, the printed circuit board including: a metal post; and an insulating layer covering at least a portion of the metal post, wherein, based on a virtual line on substantially the same level as an uppermost surface of the insulating layer, the metal post includes a first conductive portion disposed below the virtual line, a second conductive portion disposed above the virtual line, and a third conductive portion, at least a portion of the third conductive portion protruding from a side surface of the first conductive portion below the virtual line.

### CROSS-REFERENCE TO RELATED APPLICATIONS

This application claims benefit of priority to Korean Patent Application Nos. 10-2024-0042594 filed on Mar. 28, 2024 and 10-2024-0063660 filed on May 16, 2024, in the Korean Intellectual Property Office, the disclosures of which are incorporated herein by reference in its entirety.

### BACKGROUND

### 1. Field

The present disclosure relates to a printed circuit board and a manufacturing method for the same.

### 2. Description of Related Art

Recently, when mounting electronic components on a package substrate or for bonding between a main board and a package module, the use of copper posts is increasing for purposes such as pitch reduction, or the like, rather than simply using solder balls. The most common method of forming copper posts is to manufacture a package substrate with many layers as required, and then to form copper posts through a plating process using a seed layer on an outermost layer. Meanwhile, when forming a seed layer on a surface of a solder resist, adhesion may be insufficient, and thus, an additional process may be added to form physical roughness. However, in this case, there may be a possibility of damage to a surface of an insulating material, and there may be potential quality risks related to a mold in a semiconductor assembly process. In addition, when only copper posts are selectively plated, a plating area is narrow, which may result in significant thickness dispersions between copper posts at a panel level. To solve this problem, after forming the copper plating thicker than a target thickness and grinding may be performed, but in this case, grinding deviations may occur within the panel, and additional costs may increase due to the additional process.

### SUMMARY

An aspect of the present disclosure is to provide a printed circuit board including a metal post having substantially no plating deviations and securing flatness, and a method for manufacturing the same.

Another aspect of the present disclosure is to provide a printed circuit board including a metal post having excellent reliability and a method for manufacturing the same.

Another aspect of the present disclosure is to provide a printed circuit board for cost reductions and process simplification, and a method for manufacturing the same.

An aspect of the present disclosure is to process a via portion in an insulating layer with a protective layer attached thereto, form a gap portion penetrating a portion of the protective layer and/or the insulating layer from a side portion of the via portion between the protective layer and the insulating layer, perform a plating process to fill the via portion and the gap portion before peeling the protective layer, and then peel the protective layer, to form one or more metal posts having a structure having substantially no plating deviation, excellent flatness, and excellent reliability using a relatively simple process.

For example, according to an aspect of the present disclosure, a printed circuit board includes: a metal post; and an insulating layer covering at least a portion of the metal post, wherein, based on a virtual line on substantially the same level as an uppermost surface of the insulating layer, the metal post may include a first conductive portion disposed below the virtual line, a second conductive portion disposed above the virtual line, and a third conductive portion, at least a portion of the third conductive portion protruding from a side surface of the first conductive portion below the virtual line.

For example, according to an aspect of the present disclosure, a method for manufacturing a printed circuit board includes: preparing a substrate including an insulating layer and a protective layer disposed on the insulating layer; forming a via portion penetrating the protective layer in a thickness direction from an upper surface of the protective layer and further penetrating at least a portion of the insulating layer; forming a gap portion penetrating a portion of each of the insulating layer and the protective layer in a direction substantially perpendicular to the thickness direction from a side portion of the via portion, at an interface between the insulating layer and the protective layer; forming a seed layer disposed on a bottom surface of the via portion, a wall surface of the via portion, and an upper surface of the protective layer, and filling at least a portion of the gap portion; forming a metal layer disposed on the seed layer, and filling at least a portion of the via portion; removing a portion of each of the seed layer and the metal layer, to expose at least a portion of the upper surface of the protective layer; and removing the protective layer.

For example, according to an aspect of the present disclosure, a printed circuit board includes: a metal post; and an insulating layer covering at least a portion of the metal post. The metal post includes a lower portion disposed in the insulating layer, an upper portion protruding on the insulating layer, and a protruding portion protruding from a side surface of one of the lower portion and the upper portion of the metal post. The protruding portion includes a lower surface extending towards the lower portion in a direction inclined with respect to an upper surface of the insulating layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example embodiment of an electronic device system;

FIG. 2 is a perspective diagram schematically illustrating an example embodiment of an electronic device;

FIG. 3 is a cross-sectional diagram schematically illustrating an example embodiment of a printed circuit board;

FIG. 4 is a schematic plan view of the printed circuit board of FIG. 3 viewed from the top;

FIG. 5 is a schematic process diagram illustrating an example embodiment of manufacturing the metal post of FIG. 3;

FIG. 6 is a schematic cross-sectional view of another example embodiment of a printed circuit board;

FIG. 7 is a schematic plan view of the printed circuit board of FIG. 6 viewed from the top;

FIG. 8 is a schematic process diagram illustrating an example embodiment of manufacturing the metal post of FIG. 6;

FIG. 9 is a schematic cross-sectional view of another example embodiment of a printed circuit board;

FIG. 10 is a schematic plan view of the printed circuit board of FIG. 9 viewed from the top;

FIG. 11 is a schematic process diagram illustrating an example embodiment of manufacturing the metal post of FIG. 9;

FIG. 12 is a schematic cross-sectional view of another example embodiment of a printed circuit board;

FIG. 13 is a schematic plan view of the printed circuit board of FIG. 12 viewed from the top;

FIG. 14 is a schematic process diagram illustrating an example embodiment of manufacturing the metal post of FIG. 12;

FIG. 15 is a schematic cross-sectional view of another example embodiment of a printed circuit board;

FIG. 16 is a schematic plan view of the printed circuit board of FIG. 15 viewed from the top;

FIG. 17 is a schematic process diagram illustrating an example embodiment of manufacturing the metal post of FIG. 15;

FIG. 18 is a schematic cross-sectional view of another example embodiment of a printed circuit board;

FIG. 19 is a schematic plan view of the printed circuit board of FIG. 18 viewed from the top;

FIG. 20 is a schematic process diagram illustrating an example embodiment of manufacturing the metal post of FIG. 18;

FIG. 21 is a schematic cross-sectional view of another example embodiment of a printed circuit board;

FIG. 22 is a schematic plan view of the printed circuit board of FIG. 21 viewed from the top;

FIG. 23 is a schematic process diagram illustrating an example embodiment of manufacturing the metal post of FIG. 21;

FIG. 24 is a schematic cross-sectional view of another example embodiment of a printed circuit board;

FIG. 25 is a schematic plan view of the printed circuit board of FIG. 24 viewed from the top;

FIG. 26 is a schematic process diagram illustrating an example embodiment of manufacturing the metal post of FIG. 24;

FIG. 27 is a schematic cross-sectional view of another example embodiment of a printed circuit board;

FIG. 28 is a schematic plan view of the printed circuit board of FIG. 27 viewed from the top;

FIG. 29 is a schematic process diagram illustrating an example embodiment of manufacturing the metal post of FIG. 27;

FIG. 30 is a schematic cross-sectional view of another example embodiment of a printed circuit board;

FIG. 31 is a schematic plan view of the printed circuit board of FIG. 30 viewed from the top;

FIG. 32 is a schematic process diagram illustrating an example embodiment of manufacturing the metal post of FIG. 30;

FIG. 33 is a schematic cross-sectional view of another example embodiment of a printed circuit board;

FIG. 34 is a schematic plan view of the printed circuit board of FIG. 33 viewed from the top;

FIG. 35 is a schematic process diagram illustrating an example embodiment of manufacturing the metal post of FIG. 33;

FIG. 36 is a schematic cross-sectional view of another example embodiment of a printed circuit board;

FIG. 37 is a schematic plan view of the printed circuit board of FIG. 36 viewed from the top;

FIG. 38 is a schematic process diagram illustrating an example embodiment of manufacturing the metal post of FIG. 36;

FIG. 39 is a schematic cross-sectional view of another example embodiment of a printed circuit board;

FIG. 40 is a schematic plan view of the printed circuit board of FIG. 39 viewed from the top;

FIG. 41 is a schematic process diagram illustrating an example embodiment of manufacturing the metal post of FIG. 39;

FIG. 42 is a schematic cross-sectional view of another example embodiment of a printed circuit board; and

FIGS. 43 and 44 schematic process diagrams illustrating an example embodiment of manufacturing the metal post of FIG. 42.

### DETAILED DESCRIPTION

Hereinafter, embodiments of the present disclosure will be described as follows with reference to the attached drawings.

### Electronic Device

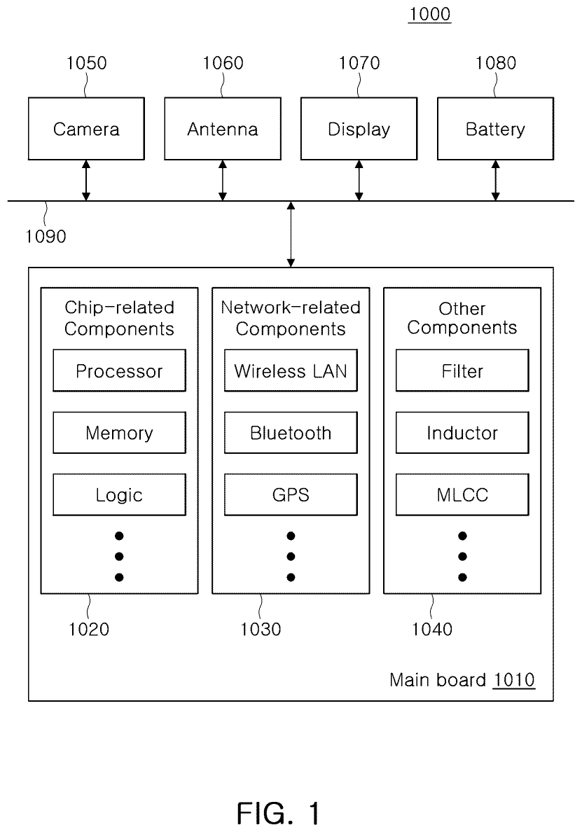

FIG. 1 is a block diagram illustrating an example embodiment of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

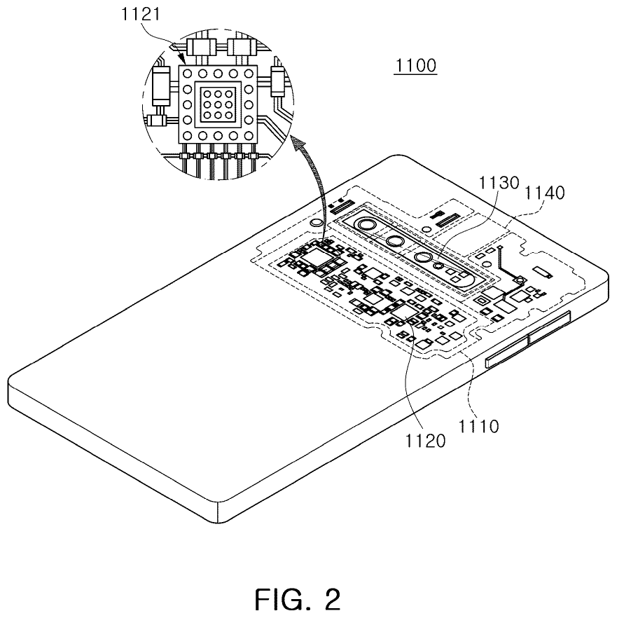

FIG. 2 is a perspective diagram illustrating an example embodiment of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

### Printed Circuit Board

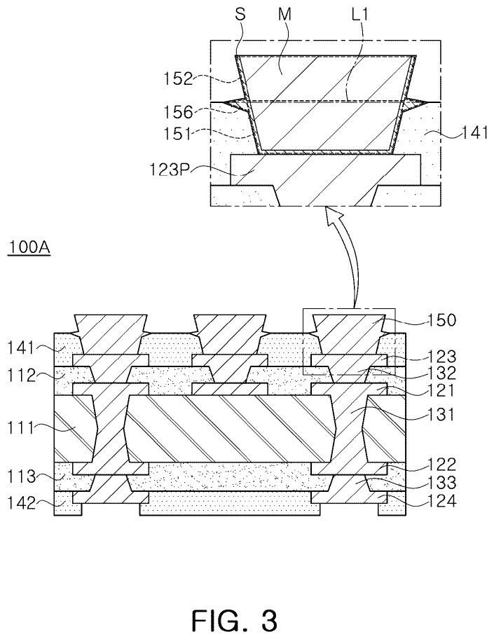

FIG. 3 is a cross-sectional view schematically illustrating an example embodiment of a printed circuit board.

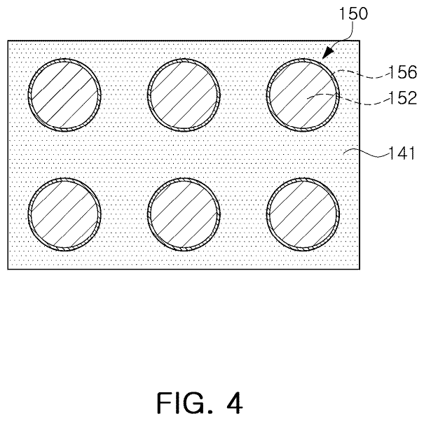

FIG. 4 is a plan view schematically illustrating a top view of the printed circuit board of FIG. 3.

Referring to the drawings, a printed circuit board 100A according to an example may include a metal post 150 and an insulating layer 141 covering a portion of the metal post 150. Based on a virtual line L1 on substantially the same level as an uppermost surface of the insulating layer 141, the metal post 150 may include a first conductive portion 151 disposed below the virtual line L1, a second conductive portion 152 disposed above the virtual line L1, and a third conductive portion 156, at least a portion of the third conductive portion 156 protruding from a side surface of the first conductive portion 151 below the virtual line L1. When the upper surface of the insulating layer 141 is not uniform, the uppermost surface of the insulating layer 141 may refer to a region disposed at the uppermost level. A plurality of such metal posts 150 may be disposed, and an upper surface of each of the plurality of metal posts 150 may be disposed on substantially the same level. For example, a metal post 150 may be manufactured by processing a via portion in an insulating layer 141 with a protective layer attached thereto, and forming a seed layer S and a metal layer M through a plating process before peeling the protective layer and then peeling the protective layer. Therefore, a plurality of metal posts 150 may be formed with a relatively simple process substantially, having no plating deviations. Therefore, a package substrate structure having secured flatness may be implemented. In addition, a gap portion G may be formed in a region adjacent to the upper surface of the insulating layer 141 during the process, and the gap portion G may be filled with the seed layer S. Accordingly, a third conductive portion 156 may be formed on a side surface of the metal post 150. Accordingly, the reliability of the metal post 150 may be further improved therethrough.

Meanwhile, at least another portion of the third conductive portion 156 may protrude from a side surface of the second conductive portion 152 above the virtual line L1. For example, at least a portion and at least another portion of the third conductive portion 156 may have a thickness which is substantially smaller toward the outside from the side surfaces of each of the first and second conductive portions 151 and 152, respectively, and therefore, the third conductive portion 156 may have a substantially pointed shape in cross-section, but the present disclosure is not limited thereto. In addition, the third conductive portion 156 may continuously surround the side surfaces of each of the first and second conductive portions 151 and 152, and thus the third conductive portion 156 may be substantially toroidal on a plane, but the present disclosure is not limited thereto. A portion of the third conductive portion 156 protruding from the side surface of the first conductive portion 151 may have a larger area in cross-section than another portion of the third conductive portion 156 protruding from the side surface of the second conductive portion 152. In this shape and disposition, the above-described reliability of the metal post 150 may be improved more effectively.

Meanwhile, the upper surface of the second conductive portion 152 may provide an upper surface of the metal post 150, and may be substantially flat overall. In this case, it may be more effective in reducing thickness deviations or height deviations between the plurality of metal posts 150. In addition, the side surfaces of each of the first and second conductive portions 151 and 152 may include a tapered region. For example, each of the first and second conductive portions 151 and 152 may have a tapered region in which a width of an upper portion thereof is greater than a width a lower portion thereof. In this case, the side surfaces of each of the first and second conductive portions 151 and 152 may have substantially the same inclination, but the present disclosure is not limited thereto. As a result, the metal post 150 may have a tapered shape, and thus it may be more effective in implementing a fine pitch.

Meanwhile, a printed circuit board 100A according to an example may further include a pad 123P. The insulating layer 141 may cover a portion of the pad 123P, and the metal post 150 may be connected to an upper surface exposed from the insulating layer 141 of the pad 123P. The metal post 150 may include a seed layer S and a metal layer M. At least a portion of the metal layer M may be disposed below the virtual line L1, and at least another portion of the metal layer M may be disposed above the virtual line L1. The seed layer S may cover at least a portion of each of a lower surface and a side surface of the metal layer M. The seed layer S may be in contact with at least another portion of the side surface disposed above the virtual line L1 of the metal layer M, but may be spaced apart from the upper surface of the metal layer M. For example, the seed layer S may cover the side surface of the metal layer M but may not cover the upper surface thereof. The first to third conductive portions 151, 152, and 156 may include a seed layer S and/or a metal layer M. Through such a structure, the flatness of the metal post 150 may be secured more easily, and the reliability of the metal post 150 may be improved more easily.

Meanwhile, a printed circuit board 100A according to an example may be a multilayer board structure including a plurality of insulating layers 111, 112, 113, 141, and 142, a plurality of wiring layers 121, 122, 123, and 124 respectively disposed on or within the plurality of insulating layers 111, 112, 113, 141, and 142, and a plurality of via layers 131, 132, and 133 respectively penetrating at least a portion of at least one of the plurality of insulating layers 111, 112, and 113. For example, the printed circuit board 100A according to an example may be a core-type multilayer board. However, the present disclosure is not limited thereto, and may be a coreless-type multilayer substrate if necessary. The wiring layer 123 disposed on an uppermost side of the plurality of wiring layers 121, 122, 123, and 124 may include the pad 123P described above, and the insulating layer 141 disposed on an uppermost side of the plurality of insulating layers 111, 112, 113, 141, and 142 may include the insulating layer 141 described above. For example, a substrate applied to the printed circuit board 100A according to an example may include a plurality of insulating layers 111, 112, 113, 141, and 142, a plurality of wiring layers 121, 122, 123, and 124, and a plurality of via layers 131, 132, and 133, and a metal post 150 may be disposed on an uppermost side on the substrate. However, the present disclosure is not limited thereto, and a metal post 150 may also be disposed lowermost on the substrate in substantially the same form. Such a metal post 150 may be used as posts for mounting electronic components. Alternatively, the metal post 150 may be used as a post for bonding with other substrates such as a main board.

Hereinafter, components of the printed circuit board 100A according to an example will be described in more detail with reference to the drawings.

A substrate including a plurality of insulating layers 111, 112, 113, 141, and 142, a plurality of wiring layers 121, 122, 123, and 124, and a plurality of via layers 131, 132, and 133 may be a core-type multilayer substrate. For example, the substrate may include a core insulating layer 111, first and second core wiring layers 121 and 122 respectively disposed on upper and lower surfaces of the core insulating layer 111, a core via layer 131 penetrating the core insulating layer 111 and connecting the first and second core wiring layers 121 and 122, one or more first build-up insulating layers 112 disposed on the upper surface of the core insulating layer 111, one or more first build-up wiring layers 123 respectively disposed on or within the one or more first build-up insulating layers 112, one or more first build-up via layers 132 respectively penetrating at least one of the one or more first build-up insulating layers 112, one or more second build-up insulating layers 113 disposed on the lower surface of the core insulating layer 111, one or more second build-up wiring layers 124 respectively disposed on or within the one or more second build-up insulating layers 113, one or more second build-up via layers 133 respectively penetrating at least one of the one or more second build-up insulating layers 113, a first outermost insulating layer 141 disposed on a first build-up insulating layer 112 disposed on an uppermost side of the one or more first build-up insulating layers 112, and a second outermost insulating layer 142 disposed on a second build-up insulating layer 113 disposed on a lowermost side of the one or more second build-up insulating layers 113. However, the present disclosure is not limited thereto, and the substrate may also be a coreless-type multilayer substrate. In addition, the substrate may also be a hybrid structure multilayer substrate including both a core-type substrate portion and a coreless-type substrate portion.

The core insulating layer 111 may include an insulating material. The insulating material may include a thermosetting resin such as an epoxy resin, a thermoplastic resin such as polyimide, or a material in which these insulating resins are mixed with an inorganic filler such as silica, or the like, or a resin impregnated into a core material such as glass fiber (glass cloth, glass fabric), or the like, together with the inorganic filler, for example, an insulating material such as copper clad laminate (CCL), or the like, but the present disclosure is not limited thereto. The core insulating layer 111 may be thicker than each of the first and second build-up insulating layers 112 and 112, but the present disclosure is not limited thereto.

Each of the plurality of first and second build-up insulating layers may include an insulating material. The insulating material may include a thermosetting resin such as an epoxy resin, a thermoplastic resin such as polyimide, or a material in which these insulating resins are mixed with an inorganic filler such as silica, or the like, or a resin impregnated into a core material such as glass fiber, or the like, together with the inorganic filler, for example, an insulating material such as Ajinomoto Build-up Film (ABF), prepreg, resin coated copper (RCC), or the like, but the present disclosure is not limited thereto. The number of layers of each of the first and second build-up insulation layers 112 and 113 is not particularly limited, and may have the same number of layers, but the present disclosure is not limited thereto.

Each of the first and second core wiring layers 121 and 122 may include a metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu). Each of the first and second core wiring layers 121 and 122 may include an electroless plating layer (or chemical copper) and an electrolytic plating layer (or electrolytic copper), but the present disclosure is not limited thereto. A sputter layer may be formed instead of an electroless plating layer (chemical copper), or both thereof may be included. In addition, copper foil may be further included. Each of the first and second core wiring layers 121 and 122 may perform various functions depending on a design thereof. For example, each of the first and second core wiring layers 121 and 122 may include a ground pattern, a power pattern, a signal pattern, and the like. Each of the patterns may include various forms such as a line, a plain, and/or a pad.

Each of the first and second build-up wiring layers 123 and 124 may include a metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu). Each of the first and second build-up wiring layers 123 and 124 may include an electroless plating layer (or chemical copper) and an electrolytic plating layer (or electrolytic copper), but the present disclosure is not limited thereto. A sputter layer may be formed instead of an electroless plating layer (chemical copper), or both thereof may be included. In addition, copper foil may be further included. Each of the first and second build-up wiring layers 123 and 124 may perform various functions depending on a design thereof. For example, each of the first and second build-up wiring layers 123 and 124 may include a ground pattern, a power pattern, a signal pattern, and the like. Each of the patterns may include various forms such as a line, a plain, and/or a pad. For example, the first build-up wiring layer 123 may include a pad 123P.

The core via layer 131 may include a through-via. The through-via may include a metal layer filling a through-hole. In addition, the through-via may include a metal layer formed on a wall surface of the through-hole and a plug filling the metal layer. The metal layer may include a metal. The metal may include copper (Cu), aluminum (Al), silver (Ag), tin (Sn), gold (Au), nickel (Ni), lead (Pb), titanium (Ti), and/or alloys thereof, and preferably, the metal may include copper (Cu), but an embodiment thereof is not limited thereto. The plug may include an ink formed of an insulating material. The metal layer may include an electroless plating layer (or chemical copper) and an electrolytic plating layer (or electrolytic copper), but the present disclosure is not limited thereto. A sputtering layer may be included instead of an electroless plating layer (or chemical copper), and both a sputtering layer and an electroless plating layer may be included if desired. The core via layer 131 may perform various functions depending on a design thereof. For example, the core via layer 131 may include a ground pattern, a power pattern, a signal pattern, and the like. The core via layer 131 may have a substantially cylindrical shape, but is not limited thereto, and may have a substantially hourglass shape.

Each of the first and second build-up via layers 131 and 132 may include microvias. A microvia may be a filled via filling a via hole, or a conformal via disposed along a wall surface of the via hole. The microvia may be disposed in a stacked type and/or staggered type. Each of the first and second build-up wiring layers 132 and 133 may include a metal, and the metal may include copper (Cu), aluminum (Al), silver (Ag), tin (Sn), gold (Au), nickel (Ni), lead (Pb), titanium (Ti), and/or alloys thereof. Preferably, the metal may include copper (Cu). Each of the first and second build-up wiring layers 132 and 133 may include an electroless plating layer (or chemical copper) and an electrolytic plating layer (or electrolytic copper), but the present disclosure is not limited thereto. A sputter layer may be formed instead of an electroless plating layer (chemical copper), or both thereof may be included. The first and second build-up via layers 132 and 133 may perform various functions depending on a design thereof. For example, the first and second build-up via layers 132 and 133 may include a ground pattern, a power pattern, a signal pattern, and the like. The microvias of the first build-up via layer 132 and the microvias of the second build-up via layer 133 may be tapered in opposite directions.

Each of the first and second outermost insulating layers 141 and 142 may include an insulating material. The insulating material may include a thermosetting resin such as an epoxy resin, a thermoplastic resin such as polyimide, or a material in which these insulating resins are mixed with an inorganic filler such as silica, or the like, for example, an insulating material such as Ajinomoto Build-up Film (ABF) or Solder Resist (SR) may be used, but the present disclosure is not limited thereto. The first and second outermost insulating layers 141 and 142 may be disposed on the uppermost and lowermost sides of the substrate to protect the internal configuration. The first outermost insulating layer 141 may include the insulating layer 141 described above. The second outermost insulating layer 142 may have an opening of a Solder Mask Defined (SMD) and/or Non-Solder Mask Defined (NSMD) type.

The metal post 150 may include a metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu). The metal post 150 may be comprised of a seed layer S and a metal layer M. The seed layer S may include an electroless plating layer (or chemical copper) and/or a stopper layer. The metal layer M may include an electrolytic plating layer (or electrolytic copper). The metal post 150 may perform various functions depending on a design thereof. For example, the metal post 150 may include a metal post for ground, a metal post for power, a metal post for signal, and the like. The metal post 150 may be used as a post for mounting electronic components and/or as a post for bonding to another substrate such as a main board. The metal post 150 may be divided into a plurality of regions, for example, into first to third conductive portions 151, 152, and 156. The first to third conductive portions 151, 152, and 156 may be integrated with each other without boundaries. For example, the first to third conductive portions 151, 152, and 156 may include the same seed layer S and/or metal layer M. A plurality of metal posts 150 may be provided, and the plurality of metal posts 150 may have almost no plating deviations. Therefore, upper surfaces of the plurality of metal posts 150 may be disposed on substantially the same level with each other.

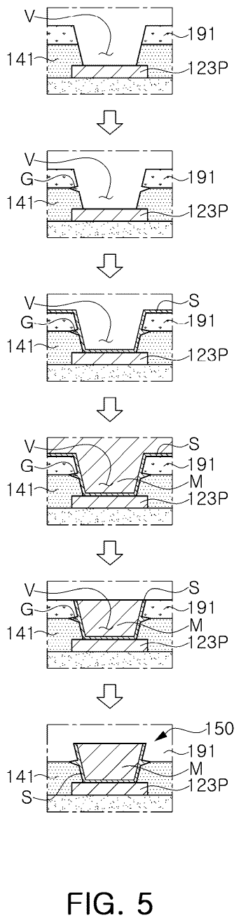

FIG. 5 is a schematic process diagram illustrating an example embodiment of manufacturing the metal post of FIG. 3.

First, a substrate including a pad 123P, an insulating layer 141 covering at least a portion of the pad 123P, and a protective layer 191 disposed on an upper surface of the insulating layer 141, may be prepared. The substrate may be the substrate described above. The insulating layer 141 may be formed by applying ABF or by laminating and drying SR. The protective layer 191 may be a protective film attached to the insulating layer 141, and may be, for example, a polyethylene terephthalate film, but the present disclosure is not limited thereto. Next, a via portion V penetrating the protective layer 191 and the insulating layer 141 in a thickness direction and exposing at least a portion of an upper surface of the pad 123P, may be formed. The via portion V may be formed by CO₂ laser processing, or the like. Next, a gap portion G penetrating a portion of each of the insulating layer 141 and the protective layer 191 in a direction substantially perpendicular to the thickness direction from a side portion of the via portion V at an interface between the protective layer 191 and the insulating layer 141. The gap portion G may be formed by a desmearing treatment. For example, a gap of about 5 μm to 15 μm may be formed at the interface between the protective layer 191 and the insulating layer 141 during the desmearing treatment.

Next, a seed layer S disposed on the bottom surface of the via portion V, for example, the exposed upper surface of the pad 123P, the wall surface of the via portion V, and the upper surface of the protective layer 191 and filling at least a portion of the gap portion G, may be formed. The seed layer S may be formed by electroless plating, for example, chemical copper. Next, a metal layer M disposed on the seed layer S and filling at least a portion of the via portion V, may be formed. The metal layer M may be formed by electrolytic plating, for example, electrolytic copper. Next, a portion of each of the seed layer S and the metal layer M may be removed. For example, a portion of each of the seed layer S and the metal layer M may be removed by an etching process to expose the protective layer 191. For example, the etching of the seed layer S and the metal layer M may be performed so that the upper surface of the metal layer M and the upper surface of the protective layer 191 are substantially coplanar. Next, the protective layer 191 may be removed. The removal of the protective layer 191 may be performed by a method of peeling the protective layer 191. By removing the protective layer 191, the via portion V may remain so that it penetrates only the insulating layer 141.

A metal post 150 may be formed through a series of processes, and since this process may be performed even when the substrate is at a panel level, when forming a plurality of metal posts 150, a structure having secured flatness may be implemented by minimizing plating deviations. In addition, since the metal post 150 includes a third conductive portion 156, reliability may also be excellent. Meanwhile, the height of the metal post 150 may be determined by an etching amount of the metal layer M. The other descriptions may be substantially the same as those described above.

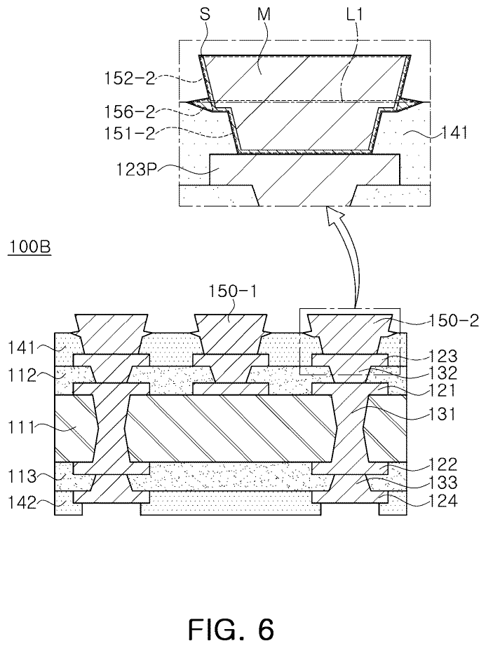

FIG. 6 is a schematic cross-sectional view of another example of a printed circuit board.

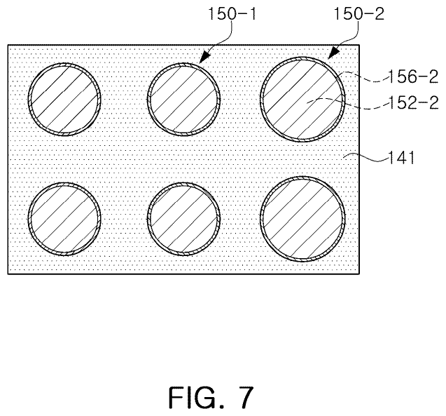

FIG. 7 is a schematic plan view of the printed circuit board of FIG. 6 viewed from the top.

Referring to the drawings, in a printed circuit board 100B according to another example, as compared to the printed circuit board 100A according to the above-described example, at least one metal post 150-2 of the plurality of metal posts 150-1 and 150-2 may have a maximum width in cross-section wider than that of at least another metal post 150-1. For example, the second conductive portion 152-2 of the at least one metal post 150-2 may have a maximum width in cross-section greater than that of the second conductive portion of the at least another metal post 150-1. Therefore, the metal posts 150-1 and 150-2 of various sizes may be formed. Meanwhile, the first and third conductive portions 151-2 and 156-2 of at least one metal post 150-2 may have a structure, material, and the like, which are generally similar to those of the first and third conductive portions of the at least another metal post 150-1. Meanwhile, at least one metal post 150-2 may have a step in cross-section between the side surfaces of each of the first and second conductive portions 151-2 and 152-2. The other descriptions may be substantially the same as those described above.

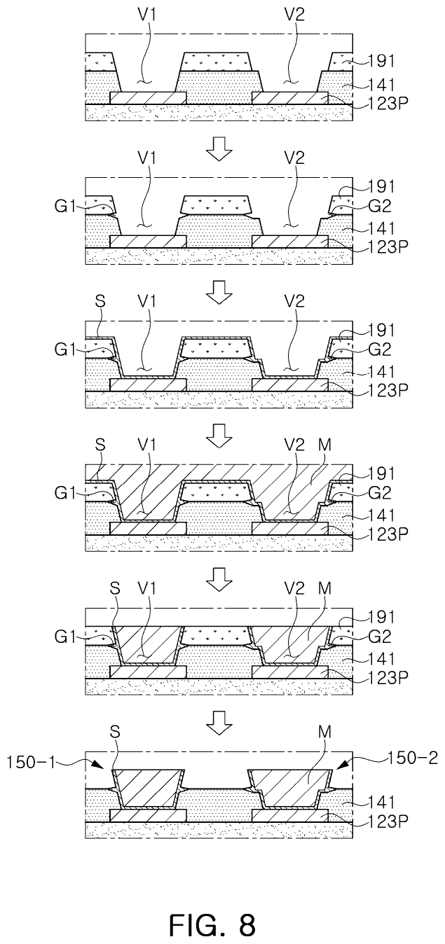

FIG. 8 is a schematic process diagram illustrating an example embodiment of manufacturing the metal post of FIG. 6.

First, a substrate may be prepared, and a plurality of via portions V1 and V2 may be formed. The plurality of via portions V1 and V2 may have different open sizes of the protective layer 191. For example, the second via portion V2 may have a larger opening size of the protective layer 191 than the first via portion V1. Next, a plurality of gap portions G1 and G2 may be formed. The plurality of gap portions G1 and G2 may have different sizes. For example, the second gap portion G2 may have a larger area than the first gap portion G1 in cross-section. Next, a seed layer S and a metal layer may be formed. Next, a portion of each of the seed layer S and the metal layer M may be removed. Next, the protective layer 191 may be removed. Metal posts 150-1 and 150-2 may be formed through a series of processes, and the other descriptions may be substantially the same as those described above.

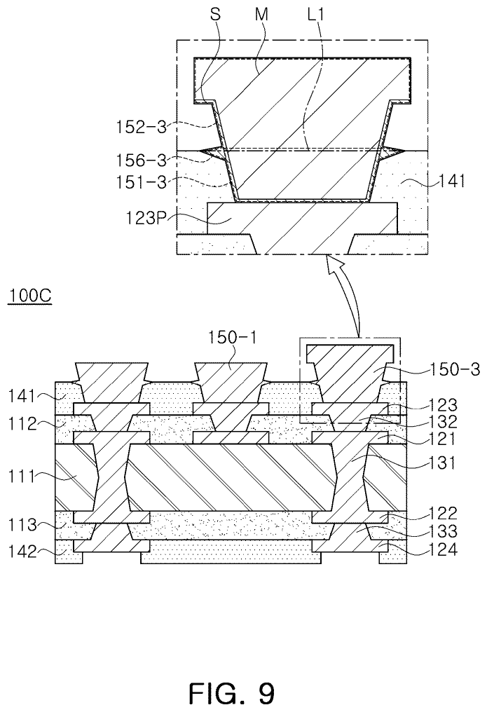

FIG. 9 is a schematic cross-sectional view of another example of a printed circuit board.

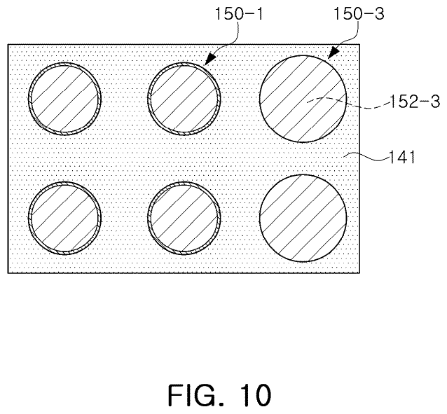

FIG. 10 is a schematic plan view of the printed circuit board of FIG. 9 viewed from the top.

Referring to the drawings, in a printed circuit board 100C according to another example, as compared to the printed circuit board 100A according to the above-described example, an upper surface of at least one metal post 150-3 of a plurality of metal posts 150-1 and 150-3 may be disposed above an upper surface of at least another metal post 150-1. For example, a second conductive portion 152-3 of at least one metal post 150-3 may have a maximum thickness or height in cross-section greater than that of the second conductive portion of the at least another metal post 150-1. For example, if necessary, the height of a portion 150-3 of the plurality of metal posts 150-1 and 150-3 may be increased. The second conductive portion 152-3 of at least one metal post 150-3 may be divided into an upper region and a lower region with different side surface inclinations. The upper and lower regions may have side surfaces having a step portion, and a minimum width of the upper region may be greater than a maximum width of the lower region, but the present disclosure is not limited thereto, and the minimum width of the upper region may be less than the maximum width of the lower region. Alternatively, the side surfaces of the upper and lower regions may be connected without a step portion, in which case the minimum width of the upper region and the maximum width of the lower region may be the same. The seed layer S may be disposed on the lower surface of the upper region of the second conductive portion 152-3 of at least one metal post 150-3, but may not be disposed on the side surface of the upper region. The remaining configuration of at least one metal post 150-3, for example, the first conductive portion 151-3, the third conductive portion 156-3, and the like, may be substantially the same as the first conductive portion, the third conductive portion, or the like, of at least another metal post 150-1. The other descriptions may be substantially the same as those described above.

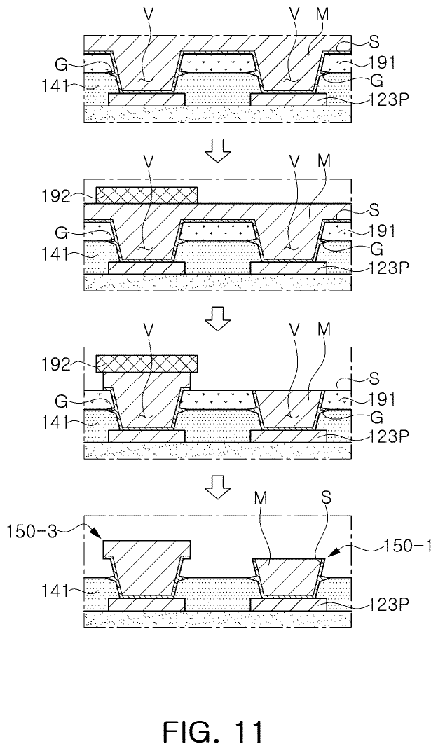

FIG. 11 is a schematic process diagram illustrating an example embodiment of manufacturing the metal post of FIG. 9.

First, a substrate may be prepared, and a plurality of via portions V may be formed. Next, a plurality of gap portions G may be formed. Next, a seed layer S and a metal layer M may be formed. Next, a portion of each of the seed layer S and the metal layer M may be removed. For example, a portion of each of the seed layer S and the metal layer M may be removed by an etching process to expose the protective layer 191. In this case, a dry film 192 may be formed on at least one via portion V so that another portion of each of the seed layer S and the metal layer M below the dry film 192 are not removed. As a result, heights of the second conductive portions 152-1 and 152-3 formed after etching may be different. Thereafter, the dry film 192 may be removed by peeling, or the like. Meanwhile, depending on the shape, size, or the like of the dry film 192, the shape, size, or the like of the second conductive portion 152-3 may be variously formed as described above. Next, the protective layer 191 may be removed. Metal posts 150-1 and 150-3 may be formed through a series of processes, and the other descriptions may be substantially the same as those described above.

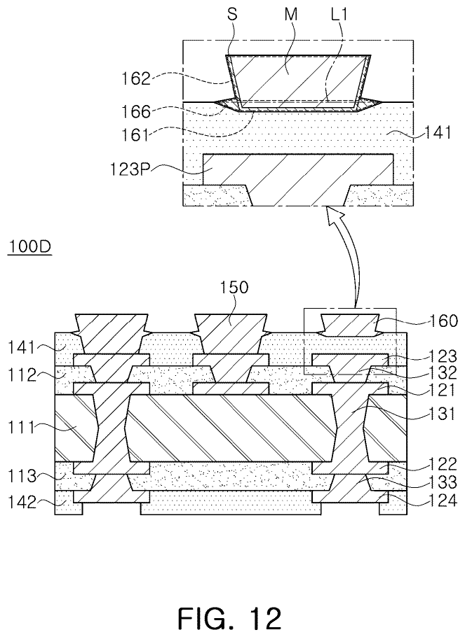

FIG. 12 is a schematic cross-sectional view of another example embodiment of a printed circuit board.

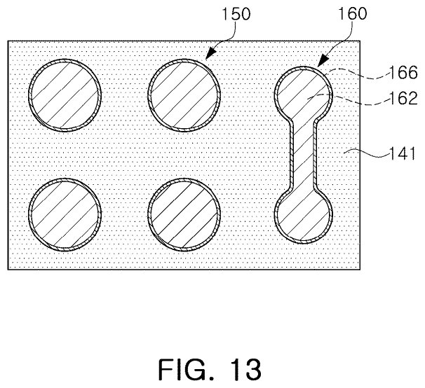

FIG. 13 is a schematic plan view of the printed circuit board of FIG. 12 viewed from the top.

Referring to the drawings, a printed circuit board 100D according to another example may further include a first metal pattern 160, as compared to the printed circuit board 100A according to the above-described example. The insulating layer 141 may cover a portion of the first metal pattern 160. The first metal pattern 160 may include a trace pattern and/or a pad pattern. The first metal pattern 160 may include a 4-1 conductive portion 161 disposed below a virtual line L1, a 5-1 conductive portion 162 disposed above the virtual line L1, and a 6-1 conductive portion 166, at least a portion of the 6-1 conductive portion 166 protruding from a side surface of the 4-1 conductive portion 161 below the virtual line L1 and at least another portion of the 6-1 conductive portion 166 protruding from a side surface of the 5-1 conductive portion 162 above the virtual line L1. The 5-1 conductive portion 162 and the 6-1 conductive portion 166 of the first metal pattern 160 may have structures, materials, and the like, which are generally similar to those of the second conductive portion and the third conductive portion of the metal post 150, respectively. An upper surface of the first metal pattern 160 may be disposed on substantially the same level as the upper surface of the metal post 150, and a lower surface of the first metal pattern 160 may be disposed above the lower surface of the metal post 150. The 4-1 conductive portion 161 of the first metal pattern 160 may have a smaller cross-sectional area, thickness, and/or depth than the first conductive portion of the metal post 150. The 4-1 conductive portion 161 of the first metal pattern 160 may have, for example, a plate shape in cross-section. The first metal pattern 160 may also include a seed layer S and a metal layer M. For example, each of the 4-1, 5-1, and 6-1 conductive portions 161, 162, and 166 may include a seed layer S and/or a metal layer M. The other descriptions may be substantially the same as those described above.

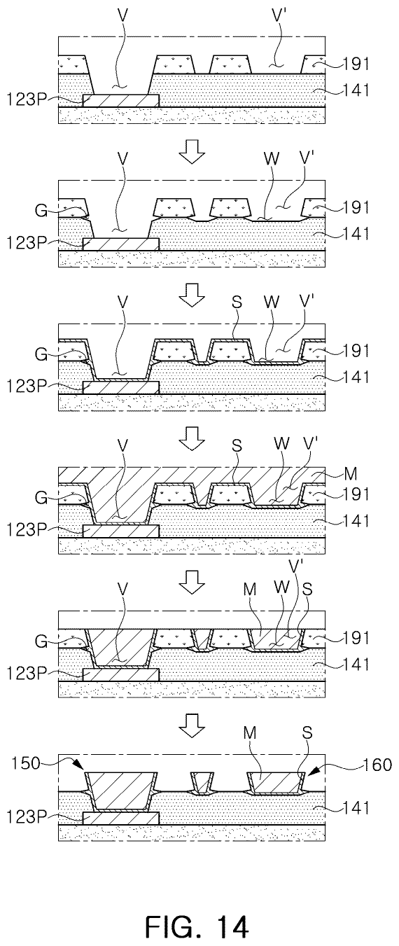

FIG. 14 is a schematic process diagram illustrating an example embodiment of manufacturing the metal post of FIG. 12.

First, a substrate may be prepared, and a via portion V may be formed. In addition, another via portion V′ penetrating the protective layer 191 in a thickness direction and exposing at least a portion of the upper surface of the insulating layer 141, may be formed. Next, a gap portion G may be formed. In addition, a groove portion W penetrating a portion of each of the protective layer 191 and the insulating layer 141 in the thickness direction below another via portion V′ and having a substantially tapered side portion in cross-section, may be formed. The gap portion G and the groove portion W may be formed by a desmearing treatment. Next, a seed layer S may be formed. The seed layer S may fill at least a portion of each of gap portion G and the groove portion W. Next, a metal layer M may be formed. The metal layer M may fill at least a portion of each of the via portion V and another via portion V′. Next, a portion of each of the seed layer S and the metal layer M may be removed. Next, the protective layer 191 may be removed. Through a series of processes, a metal post 150 and a first metal pattern 160 may be formed, and the other descriptions may be substantially the same as those described above.

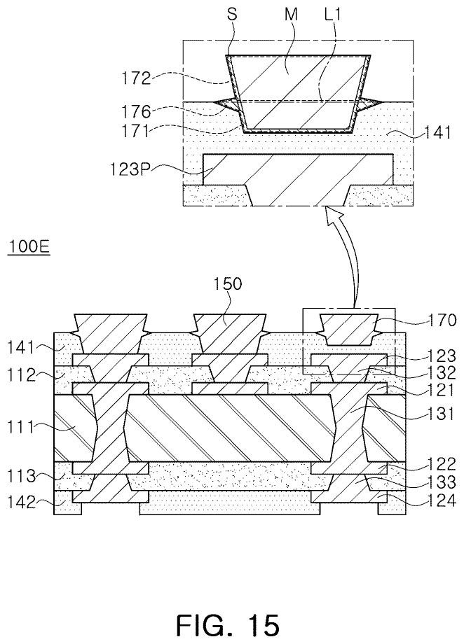

FIG. 15 is a schematic cross-sectional view of another example embodiment of a printed circuit board.

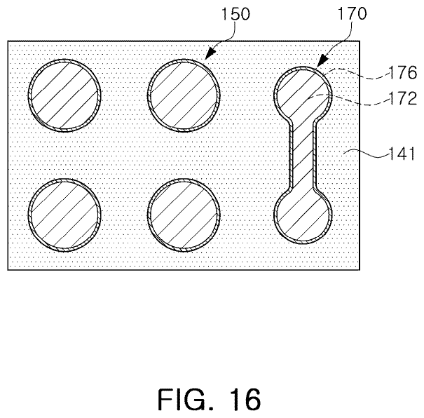

FIG. 16 is a schematic plan view of the printed circuit board of FIG. 15 viewed from the top.

Referring to the drawings, in a printed circuit board 100E according to another example, as compared to the printed circuit board 100D according to another example described above, a 4-2 conductive portion 171 of the second metal pattern 170 may be formed thicker and/or deeper than the 4-1 conductive portion of the first metal pattern described above. The 5-2 conductive portion 172, the 6-2 conductive portion 176, and the like, of the second metal pattern 170 may have a cross-sectional structure which is generally similar to that of the above-described second conductive portion, third conductive portion, and the like, of the metal post 150, respectively. The second metal pattern 170 may also include a seed layer S and a metal layer M. For example, each of the 4-2, 5-2, and 6-2 conductive portions 171, 172, and 176 may include a seed layer S and/or a metal layer M. The other descriptions may be substantially the same as those described above.

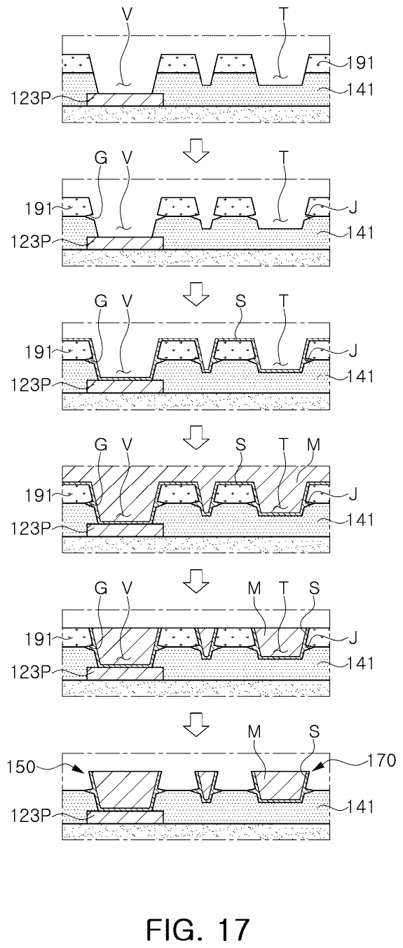

FIG. 17 is a schematic process diagram illustrating an example embodiment of manufacturing the metal post of FIG. 15.

First, a substrate may be prepared, and a via portion V may be formed. In addition, a trench portion T penetrating a portion of the protective layer 191 and the insulating layer 141 in a thickness direction and exposing at least a portion of the insulating layer 141, may be formed. A depth of the via portion V may be deeper than a depth of the trench portion T. Next, a gap portion G may be formed. In addition, another gap portion J penetrating a portion of each of the protective layer 191 and the insulating layer 141 in a direction substantially perpendicular to the thickness direction from a side portion of the trench portion T, may be formed. The gap portion G and another gap portion J may be formed by a desmearing treatment. Next, a seed layer S may be formed. The seed layer S may be further disposed on a bottom surface of the trench portion T, a wall surface of the trench portion T, and the upper surface of the protective layer 191, and may further fill at least a portion of another gap portion J. Next, a metal layer M may be formed. The metal layer M may further fill at least a portion of the trench portion T. Next, a portion of each of the seed layer S and the metal layer M may be removed. Next, the protective layer 191 may be removed. A metal post 150 and a second metal pattern 170 may be formed through a series of processes, and the other descriptions may be substantially the same as those described above.

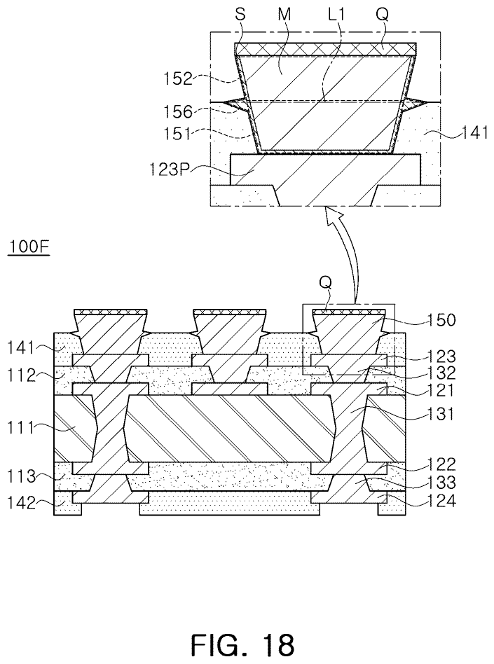

FIG. 18 is a schematic cross-sectional view of another example embodiment of a printed circuit board.

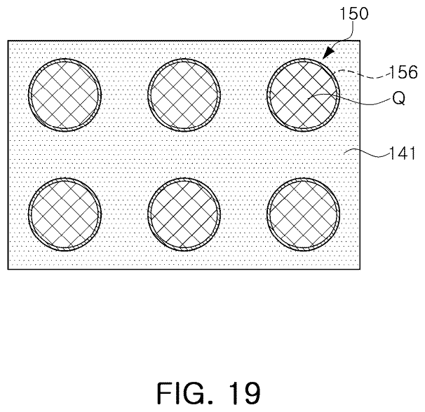

FIG. 19 is a schematic plan view of the printed circuit board of FIG. 18 viewed from the top.

Referring to the drawings, in a printed circuit board 100F according to another example, as compared to the printed circuit board 100A according to the above-described example, a surface treatment layer Q may be further disposed on an upper surface of the metal post 150. The surface treatment layer Q may include, for example, at least one of a tin (Sn) layer and a gold (Au) layer, but the present disclosure is not limited thereto. The surface treatment layer Q may cover an upper surface of the metal post 150, for example, an upper surface of the second conductive portion 152, but may be spaced apart from a side surface of the second conductive portion 152, but the present disclosure is not limited thereto. The bonding reliability may be improved through the surface treatment layer Q. The other descriptions may be substantially the same as those described above.

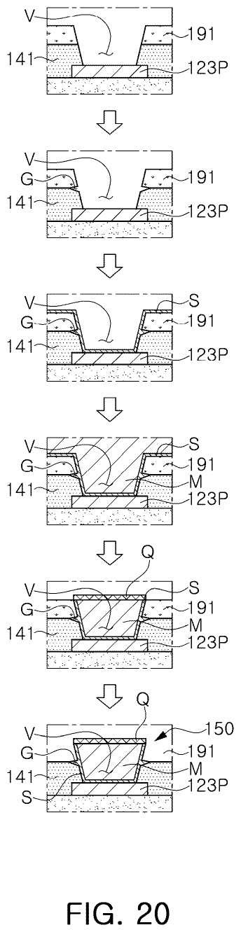

FIG. 20 is a schematic process diagram illustrating an example embodiment of manufacturing the metal post of FIG. 18.

First, a substrate may be prepared, and a via portion V may be formed. Next, a gap portion G may be formed. Next, a seed layer S and a metal layer M may be formed. Next, a portion of each of the seed layer S and the metal layer M may be removed. Next, a surface treatment layer Q may be formed on the exposed upper surface of each of the seed layer S and the metal layer M. The surface treatment layer Q may be formed by, for example, electrolytic gold plating, electroless gold plating, organic solderability preservative (OSP) or electroless tin plating, electroless silver plating, electroless nickel plating/substitution gold plating, direct immersion gold (DIG) plating, hot air solder leveling (HASL), or the like, but the present disclosure is not limited thereto. Next, a protective layer 191 may be removed. If necessary, a surface treatment layer Q may be formed after removing the protective layer 191. The metal post 150 described above and the surface treatment layer Q covering the metal post may be formed through a series of processes, and the other descriptions may be substantially the same as those described above.

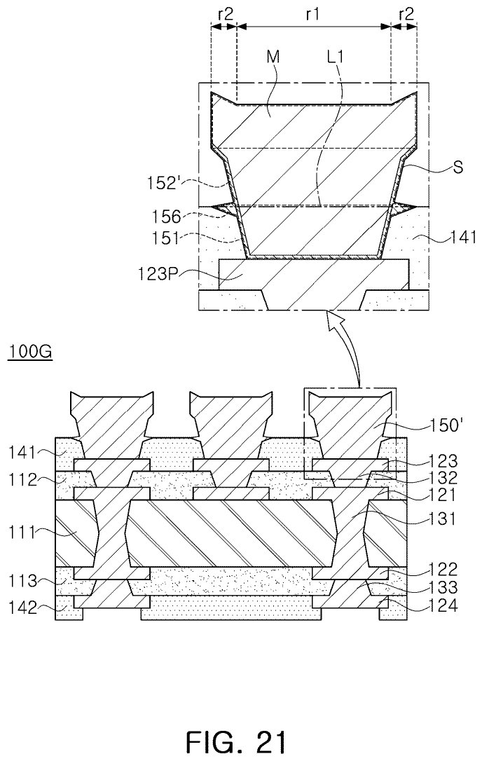

FIG. 21 is a schematic cross-sectional view of another example embodiment of a printed circuit board.

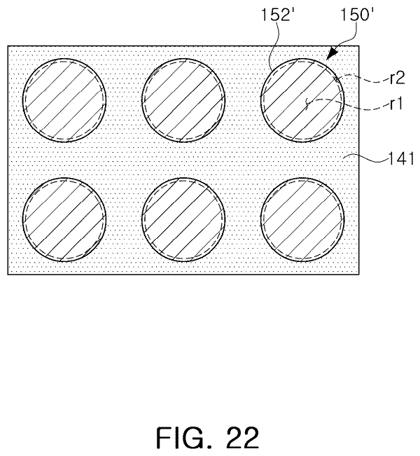

FIG. 22 is a schematic plan view of the printed circuit board of FIG. 21 viewed from the top.

Referring to the drawings, in a printed circuit board 100G according to another example, as compared to the printed circuit board 100A according to the above-described example, an upper surface of a second conductive portion 152′ may include a central region r1 and an edge region r2 surrounding the central region r1 and at least a portion of which protrudes upwardly from the central region r1. A protrusion height of at least a portion of the edge region r2 may be within approximately 5 μm. For example, the central region r1 of the upper surface of the second conductive portion 152′ of the metal post 150′ may be substantially flat, and the edge region r2 may be substantially pointed upwardly. In addition, based on the virtual line L1, a maximum height of the central region r1 may be smaller than a maximum height of the edge region r2. In addition, the second conductive portion 152′ of the metal post 150′ may be formed thicker, and a side surface of the second conductive portion 152′ may include a plurality of regions having different inclinations. A second conductive portion 152′ having such a shape may be formed in the process of peeling a portion of the plating layer from the protective layer, which may be a structural result that can support a process described below. The seed layer S may be in contact with a portion of a side surface of the region of the metal layer M disposed above the virtual line L1, but may be spaced apart from another portion of the side surface thereof. In addition, the seed layer S may be spaced apart from the upper surface of the metal layer M. For example, the seed layer S may not cover the upper surface of the metal layer M, and a portion of the side surface of the metal layer M which is connected to the upper surface of the metal layer M. In this shape and disposition, the reliability of the metal post 150′ may be improved more effectively. In addition, it may be more effective in reducing thickness deviations and/or height deviations between the plurality of metal posts 150′. In addition, it may be more effective in implementing a fine pitch. The other descriptions may be substantially the same as those described above.

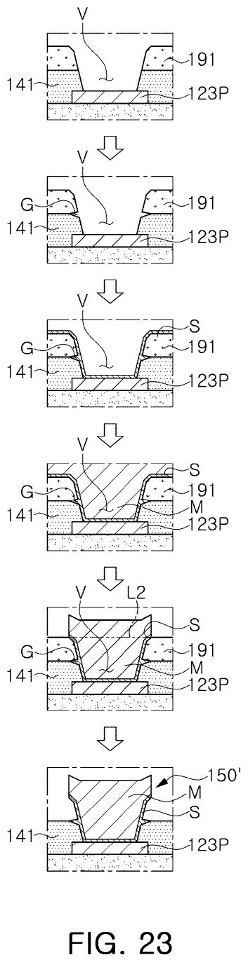

FIG. 23 is a process diagram schematically illustrating an example embodiment of manufacturing the metal post of FIG. 21.

First, a substrate may be prepared, and a via portion V may be formed. Next, a gap portion G may be formed. Next, a seed layer S and a metal layer M may be formed. Next, a portion of each of the seed layer S and the metal layer M may be removed. For example, a portion of each of the seed layer S and the metal layer M may be peeled from a protective layer 191. As a result, the protective layer 191 may be exposed. In this case, based on a virtual line L2 which is substantially at the same level as the uppermost surface of the protective layer 191, another portion of the metal layer M may remain above the virtual line L2. In addition, at least a portion of the edge region surrounding the central region of the upper surface of the metal layer M may protrude upwardly of the central region. For example, the above-described pointed shape may be formed. However, the present disclosure is not limited thereto, and when physically peeling a portion of each of the seed layer S and the metal layer M from the protective layer 191, when a mask is attached to the upper surface of another portion of the metal layer M, the upper surface of the metal layer M may not have the above-described pointed shape, but may have an overall flat shape. Meanwhile, the uppermost surface of the protective layer 191 may mean a region disposed at the uppermost level when the upper surface of the protective layer 191 is not uniform. As described above, the height of the metal post 150′ may be determined by the thickness of the protective layer 191 and the thickness of the electroplating layer. Next, the protective layer 191 may be removed. The metal post 150′ described above can be formed through a series of processes, and the other descriptions may be substantially the same as those described above.

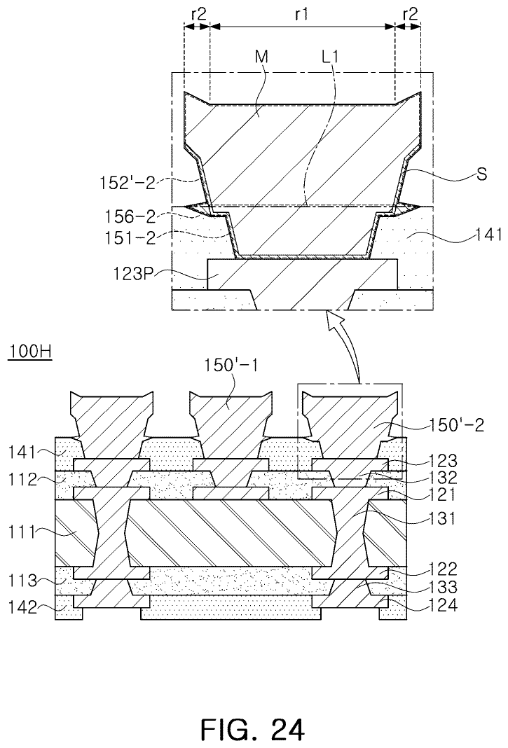

FIG. 24 is a schematic cross-sectional view of another example of a printed circuit board.

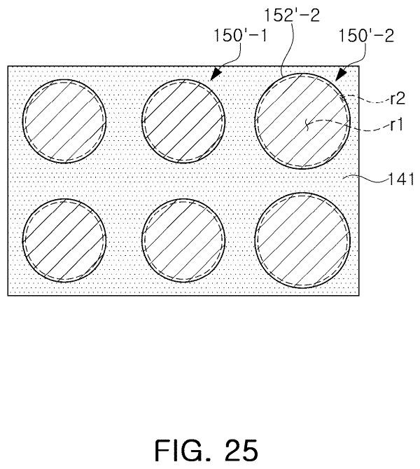

FIG. 25 is a schematic plan view of the printed circuit board of FIG. 24 viewed from the top.

Referring to the drawings, in a printed circuit board 100H according to another example, as compared to the printed circuit board 100G according to another example described above, at least one metal post 150′-2 of the plurality of metal posts 150′-1 and 150′-2 may have a maximum width in cross-section wider than at least another metal post 150′-1. For example, the second conductive portion 152′-2 of at least one metal post 150′-2 may have a maximum width in cross-section greater than that of the second conductive portion of at least another metal post 150′-1. Accordingly, the metal posts 150′-1 and 150′-2 of various sizes may be formed. Meanwhile, the first and third conductive portions 151-2 and 156-2 of at least one metal post 150-2 may have similar structures, materials, and the like, to those of the first and third conductive portions of at least another metal post 150′-1. Meanwhile, at least one metal post 150′-2 may have a step in cross-section between the side surface of each of the first and second conductive portions 151-2 and 152′-2. The other descriptions may be substantially the same as those described above.

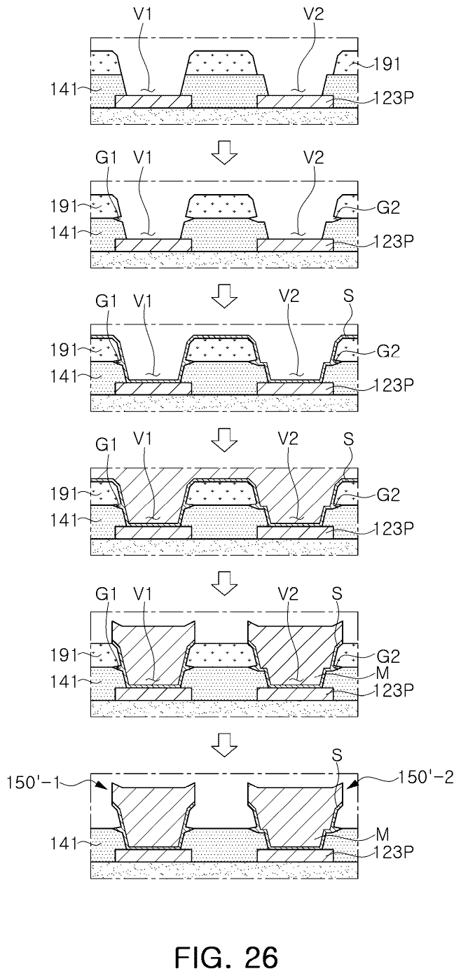

FIG. 26 is a process diagram schematically illustrating an example embodiment of manufacturing the metal post of FIG. 24.

First, a substrate may be prepared, and a plurality of via portions V1 and V2 may be formed. The plurality of via portions V1 and V2 may have different open sizes of the protective layer 191. For example, the second via portion V2 may have a larger opening size of the protective layer 191 than the first via portion V1. Next, a plurality of gap portions G1 and G2 respectively penetrating a portion of the insulating layer 141 in a direction substantially perpendicular to a thickness direction from a side portion of the plurality of via portions V1 and V2 at an interface between the protective layer 191 and the insulating layer 141. The plurality of gap portions G1 and G2 may have different sizes. For example, the second gap portion G2 may have a larger area than the first gap portion G1 in cross-section, but the present disclosure is not limited thereto. Next, a seed layer S and a metal layer M may be formed. Next, a portion of each of the seed layer S and the metal layer M may be removed. Next, the protective layer 191 may be removed. A plurality of metal posts 150′-1 and 150′-2 may be formed through a series of processes, and the other descriptions may be substantially the same as those described above.

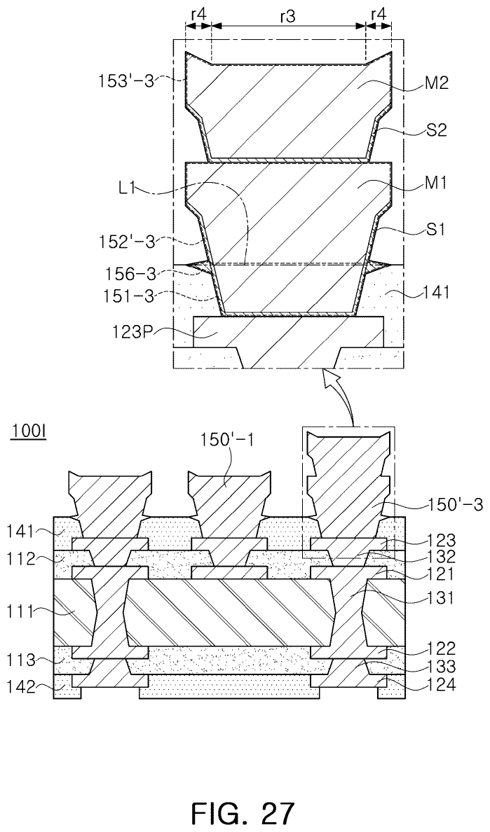

FIG. 27 is a schematic cross-sectional view of another example of a printed circuit board.

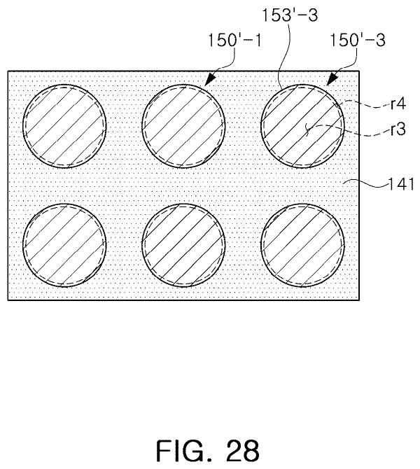

FIG. 28 is a schematic plan view of the printed circuit board of FIG. 27 viewed from the top.

Referring to the drawings, in a printed circuit board 100I according to another example, as compared to the printed circuit board 100G according to another example described above, an upper surface of at least one 150′-3 of the plurality of metal posts 150′-1 and 150′-3 may be disposed above an upper surface of at least another metal post 150′-1. For example, if necessary, a height of at least a portion 150′-3 of the plurality of metal posts 150′-1 and 150′-3 may be increased. For example, at least one metal post 150′-3 may further include an additional conductive portion 153′-3. The additional conductive portion 153′-3 may have a structure and material substantially similar to that of the second conductive portion of at least another metal post 150′-1. For example, the additional conductive portion 153′-3 may include an upper surface having a central region r3 and an edge region r4 surrounding the central region r3 and at least a portion of which protrudes upwardly from the central region r3. The additional conductive portion 153′-3 may include a second seed layer S2 and a second metal layer M2 which are distinct from the first seed layer S1 and the first metal layer M1. The remaining configuration of at least one metal post 150′-3, such as the first to third conductive portions 151-3, 152′-3, and 156-3, may have a structure and material which are substantially similar to those of the first to third conductive portions of at least another metal post 150-1. The other descriptions may be substantially the same as those described above.

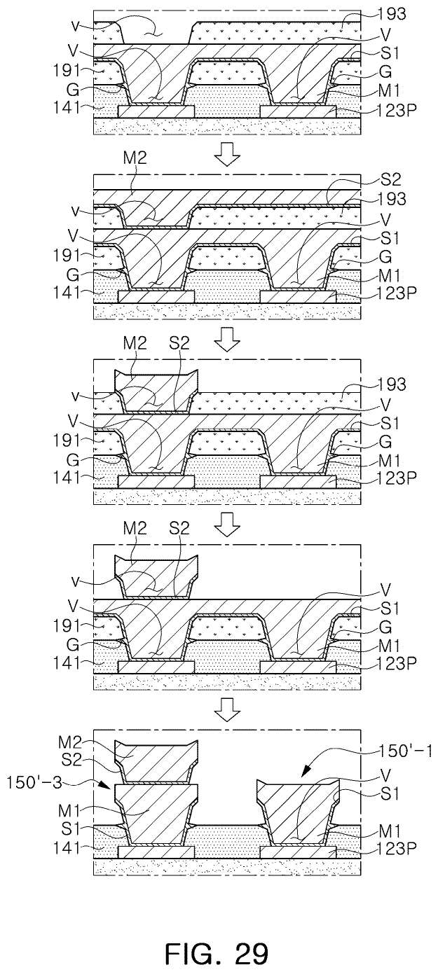

FIG. 29 is a process diagram schematically illustrating an example embodiment of manufacturing the metal post of FIG. 27.

First, a substrate may be prepared, and a plurality of via portions V and a plurality of gap portions G may be formed. Next, a first seed layer S1 and a first metal layer M1 may be formed. Next, a second protective layer 193 may be attached to the first metal layer M1. The second protective layer 193 may be a protective film, for example, a polyethylene terephthalate film, but the present disclosure is not limited thereto. Next, an additional via portion (v) penetrating the second protective layer 193 and exposing at least a portion of the upper surface of the first metal layer M1, may be formed. The additional via portion (v) may be formed by CO₂ laser processing, or the like. Next, a second seed layer S2 disposed on a bottom surface of the additional via portion (v), for example, the exposed upper surface of the first metal layer M1, a wall surface of the additional via portion (v), and an upper surface of the second protective layer 193, may be formed. The second seed layer S2 may be formed by electroless plating, for example, by chemical copper. Next, a second metal layer M2 disposed on the second seed layer S2 and filling at least a portion of the additional via portion (v), may be formed. The second metal layer M2 may be formed by electrolytic plating, for example, electrolytic copper. Next, a portion of each of the second seed layer S2 and the second metal layer M2 may be removed. For example, a portion of each of the second seed layer S2 and the second metal layer M2 may be peeled from the second protective layer 193. As the result, the second protective layer 193 may be exposed. In this case, a protruding shape or a pointed shape may be formed on the upper surface of the remaining second metal layer M2. Next, the second protective layer 193 may be removed. The removal of the second protective layer 193 may be performed by a method of peeling the second protective layer 193. Next, a portion of each of the first seed layer S1 and the first metal layer M1 may be removed. Next, the first protective layer 191 may be removed. A plurality of metal posts 150′-1 and 150′-3 may be formed through a series of processes, and the other descriptions may be substantially the same as those described above.

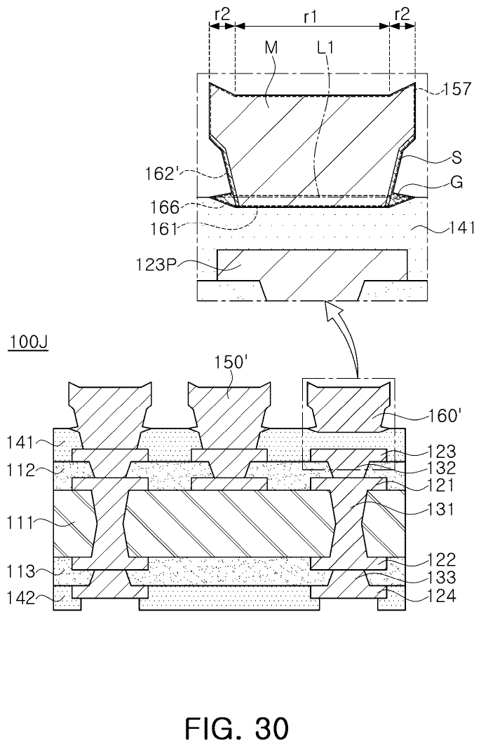

FIG. 30 is a schematic cross-sectional view of another example of a printed circuit board.

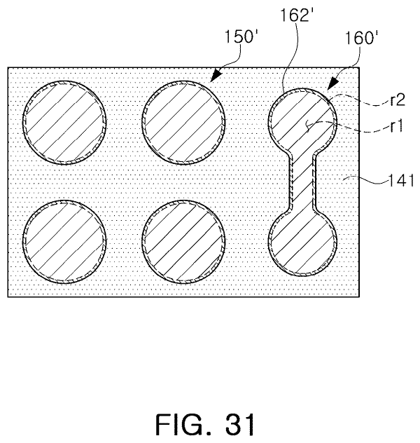

FIG. 31 is a schematic plan view of the printed circuit board of FIG. 30 viewed from the top.

Referring to the drawings, a printed circuit board 100J according to another example may further include a first metal pattern 160′ disposed on an upper side of an insulating layer 141, as compared to the printed circuit board 100G according to another example described above. The first metal pattern 160′ may include a trace pattern and/or a pad pattern. The first metal pattern 160′ may include a 4-1 conductive portion 161 disposed below a virtual line L, a 5-1 conductive portion 162′ disposed above the virtual line L, and a 6-1 conductive portion 166, at least a portion of the 6-1 conductive portion 166 protruding from a side surface of the 4-1 conductive portion 161 below the virtual line L1 and at least another portion of the 6-1 conductive portion 166 protruding from a side surface of the 5-1 conductive portion 162′ above the virtual line L1. The 5-1 conductive portion 162′ and the 6-1 conductive portion 166 of the first metal pattern 160′ may have similar structures, materials, or the like, to the second conductive portion and the third conductive portion of the metal post 150′, respectively. An upper surface of the first metal pattern 160′ may be disposed on substantially the same level as the upper surface of the metal post 150′, and a lower surface of the first metal pattern 160′ may be disposed above the lower surface of the metal post 150′. The 4-1 conductive portion 161 of the first metal pattern 160′ may have a smaller cross-sectional area, thickness, and/or depth than the first conductive portion of the metal post 150′. The 4-1 conductive portion 161 of the first metal pattern 160′ may have, for example, a plate shape in cross-section. The first metal pattern 160′ may also include a seed layer S and a metal layer M. For example, each of the 4-1, 5-1, and 6-1 conductive portions 161, 162′, and 166 may include a seed layer S and/or a metal layer M. The other descriptions may be substantially the same as those described above.

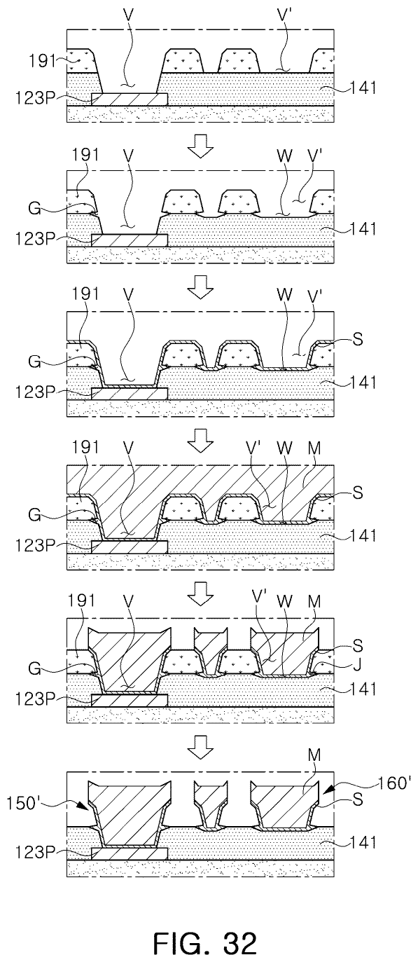

FIG. 32 is a process diagram schematically illustrating an example embodiment of manufacturing the metal post of FIG. 30.

First, a substrate may be prepared, and a via portion V may be formed. In addition, another via portion V′ penetrating the protective layer 191 in a thickness direction and exposing at least a portion of the upper surface of the insulating layer 141, may be formed. Next, a gap portion G may be formed. In addition, a groove portion W penetrating a portion of each of the protective layer 191 and the insulating layer 141 in the thickness direction below another via portion V′ and having a substantially tapered side portion in cross-section, may be formed. The gap portion G and the groove portion W may be formed by a desmearing treatment. Next, the seed layer S may be formed. The seed layer S may fill at least a portion of each of the gap portion G and the groove portion W. Next, a metal layer M may be formed. The metal layer M may fill at least a portion of each of the via portion V and another via portion V′. Next, a portion of each of the seed layer S and the metal layer M may be removed. Next, the protective layer 191 may be removed. Through a series of processes, a metal post 150′ and a first metal pattern 160′ may be formed, and the other descriptions may be substantially the same as those described above.

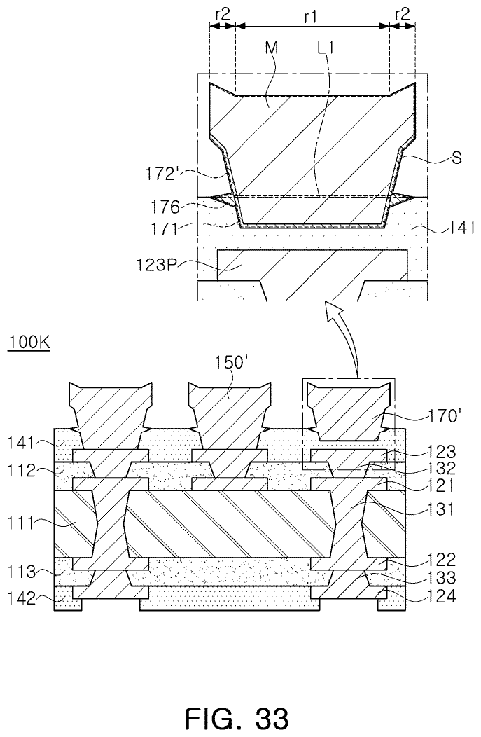

FIG. 33 is a schematic cross-sectional view of another example of a printed circuit board.

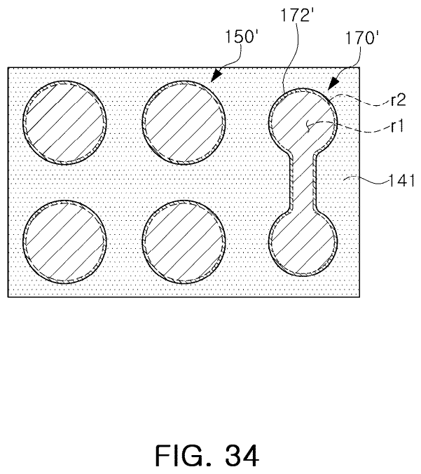

FIG. 34 is a schematic plan view of the printed circuit board of FIG. 33 viewed from the top.

Referring to the drawings, in a printed circuit board 100K according to another example embodiment, as compared to the printed circuit board 100J according to another example embodiment described above, a 4-2 conductive portion 171 of the second metal pattern 170′ may be formed thicker and/or deeper than the 4-1 conductive portion of the first metal pattern described above. A 5-2 conductive portion 172′, a 6-2 conductive portion 176, and the like, of the second metal pattern 170′ may have a cross-sectional structure similar to that of the second conductive portion, the third conductive portion, and the like, of the metal post 150′, respectively. The second metal pattern 170′ may also include a seed layer S and a metal layer M. For example, the 4-2, 5-2, and 6-2 conductive portions 171, 172′, and 176 may include a seed layer S and/or a metal layer M, respectively. The other descriptions may be substantially the same as those described above.

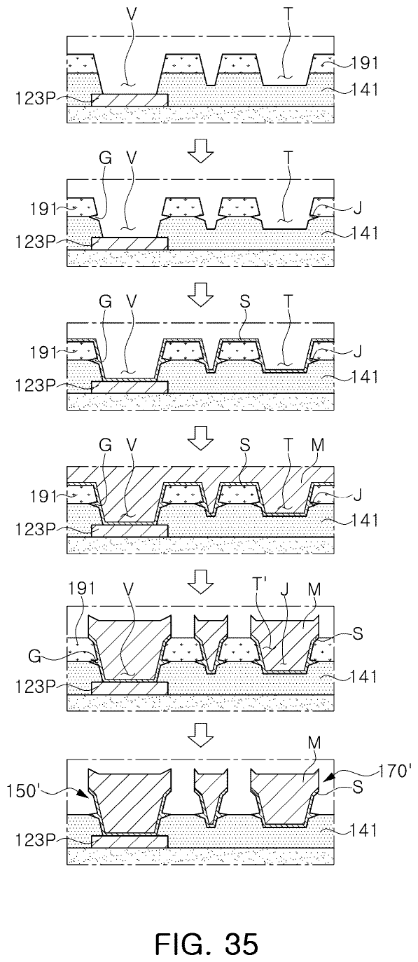

FIG. 35 is a process diagram schematically illustrating an example embodiment of manufacturing the metal post of FIG. 33.

First, a substrate may be prepared, and a via portion V may be formed. In addition, a trench portion T penetrating a portion of the protective layer 191 and the insulating layer 141 in a thickness direction and exposing at least a portion of the insulating layer 141 may be formed. A depth of the via portion V may be deeper than a depth of the trench portion T. Next, a gap portion G may be formed. In addition, another gap portion J penetrating a portion of each of the protective layer 191 and the insulating layer 141 may be formed in a direction substantially perpendicular to a thickness direction from a side portion of the trench portion T. The gap portion G and another gap portion J may be formed by desmearing treatment. Next, a seed layer S may be formed. The seed layer S may be further disposed on the bottom surface of the trench portion T, the wall surface of the trench portion T, and the upper surface of the protective layer 191, and may further fill at least a portion of another gap portion J. Next, a metal layer M may be formed. The metal layer M may further fill at least a portion of the trench portion T. Next, a portion of each of the seed layer S and the metal layer M may be removed. Next, the protective layer 191 may be removed. Through a series of processes, a metal post 150′ and a second metal pattern 170′ may be formed, and the other descriptions may be substantially the same as those described above.

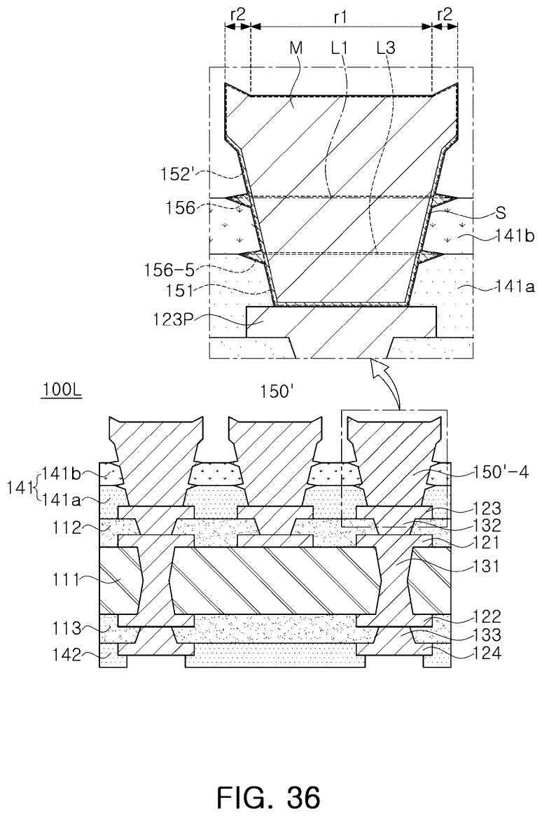

FIG. 36 is a schematic cross-sectional view of another example of a printed circuit board.

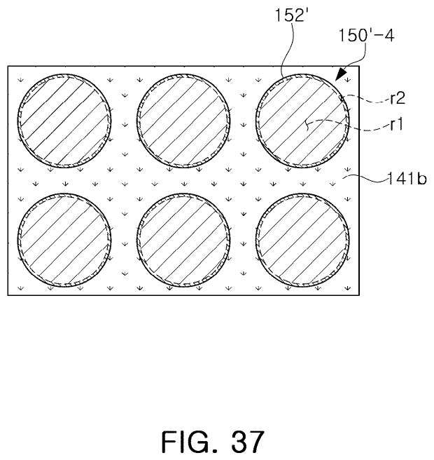

FIG. 37 is a schematic plan view of the printed circuit board of FIG. 36 viewed from the top.

Referring to the drawings, in a printed circuit board 100L according to another example, as compared to the printed circuit board 100G according to another example described above, an insulating layer 141 may include a first insulating material 141a and a second insulating material 141b disposed on the first insulating material 141a. The first insulating material 141a and the second insulating material 141b may include different insulating materials, for example, ABF and SR, respectively, but the present disclosure is not limited thereto. Based on a virtual line L3 which is substantially at the same level as an interface with the first and second insulating materials 141a and 141b, a metal post 150′-4 may further include a third conductive portion 156-5, at least a portion of the third conductive portion 156-5 protruding from a side surface of the first conductive portion 151 below the virtual line L3, and at least another portion of the third conductive portion 156-5 protruding from the side surface of the first conductive portion 151 above the virtual line L3. Another third conductive portion 156-5 may be substantially the same as the third conductive portion 156, but the present disclosure is not limited thereto. Meanwhile, the metal post 150′-4 may have improved reliability. The other descriptions may be substantially the same as those described above.

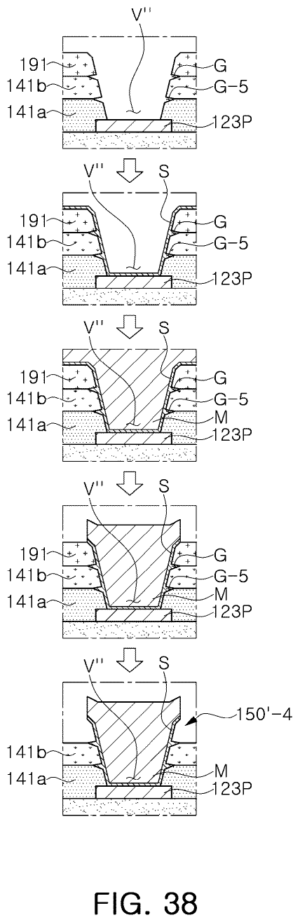

FIG. 38 is a schematic process diagram illustrating an example embodiment of manufacturing the metal post of FIG. 36.

First, a substrate may be prepared. An insulating layer 141 of the substrate may include a first insulating material 141a covering at least a portion of the pad 123P and a second insulating material 141b disposed on an upper surface of the first insulating material 141a. A protective layer 191 may be disposed on an upper surface of the second insulating material 141b. Next, a via portion V″ penetrating the protective layer 191 and the first and second insulating materials 141a and 141b in a thickness direction and exposing at least a portion of the upper surface of the pad 123P may be formed. Next, a gap portion G penetrating at least a portion of each of the second insulating material 141b and the protective layer 191 in a direction substantially perpendicular to the thickness direction from a side portion of the via portion V″ at an interface between the second insulating material 141b and the protective layer 191. In addition, another gap portion G-5 penetrating a portion of each of the first and second insulating materials 141a and 141b in a direction substantially perpendicular to the thickness direction from the side portion of the via portion V″ at an interface between the first and second insulating materials 141a and 141b. Next, a seed layer S may be formed. The seed layer S may fill at least a portion of each of the gap portion G and another portion G-5. Next, a metal layer M may be formed. Next, a portion of each of the seed layer S and the metal layer M may be removed. Next, the protective layer 191 may be removed. A metal post 150′-4 may be formed through a series of processes, and the other descriptions may be substantially the same as those described above.

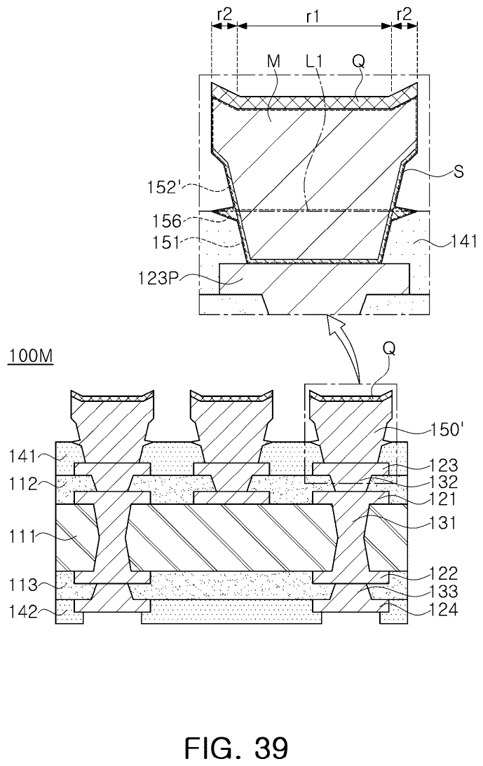

FIG. 39 is a schematic cross-sectional view of another example of a printed circuit board.

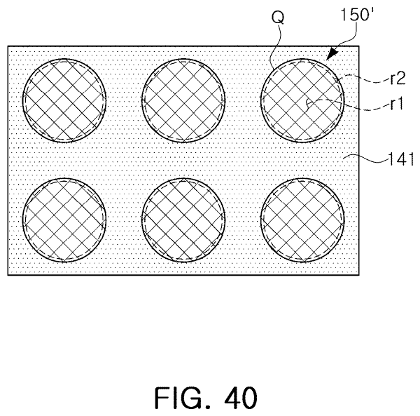

FIG. 40 is a schematic plan view of the printed circuit board of FIG. 39 viewed from the top.

Referring to the drawings, a printed circuit board 100M according to another example may further have a surface treatment layer Q disposed on an upper surface of the metal post 150′ as compared to the printed circuit board 100G according to another example described above. The surface treatment layer Q may include, for example, one or more of a tin Sn layer and a gold Au layer, but the present disclosure is not limited thereto. The surface treatment layer Q may cover the upper surface of the metal post 150′, for example, an upper surface of the second conductive portion 152′, and may be spaced apart from a side surface of the metal post 150′, for example, a side surface of the second conductive portion 152, but the present disclosure is not limited thereto. Through the surface treatment layer (Q), the reliability of bonding with electronic components and/or the reliability of bonding with a main board may be improved. The other descriptions may be substantially the same as those described above.

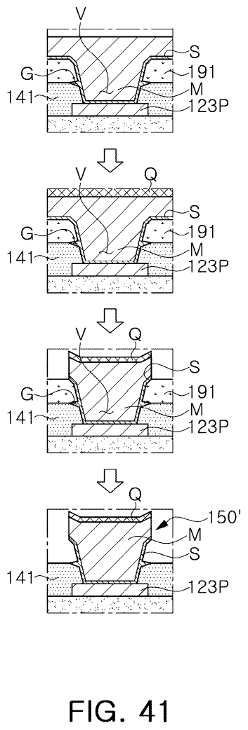

FIG. 41 is a schematic process diagram illustrating an example embodiment of manufacturing the metal post of FIG. 39.

First, a substrate may be prepared and a via portion V may be formed. Next, a gap portion G may be formed. Next, a seed layer S and a metal layer M may be formed. Next, a surface treatment layer Q may be formed on the metal layer M. The surface treatment layer Q may be formed by, for example, electrolytic gold plating, electroless gold plating, organic solderability preservative (OSP) or electroless tin plating, electroless silver plating, electroless nickel plating/substitution gold plating, direct immersion gold (DIG) plating, hot air solder leveling (HASL), or the like, but the present disclosure is not limited thereto. Next, a portion of each of the seed layer S and the metal layer M may be removed. For example, a portion of each of the seed layer S and the metal layer M may be peeled from the protective layer 191. In this case, a portion of the surface treatment layer Q may also be peeled and removed. In addition, a pointed protrusion may be formed on an upper surface of each of the metal layer M and the surface treatment layer Q. Next, a protective layer 191 may be removed. Through a series of processes, the metal post 150′ described above and the surface treatment layer Q covering the metal post may be formed. The other descriptions may be substantially the same as those described above.

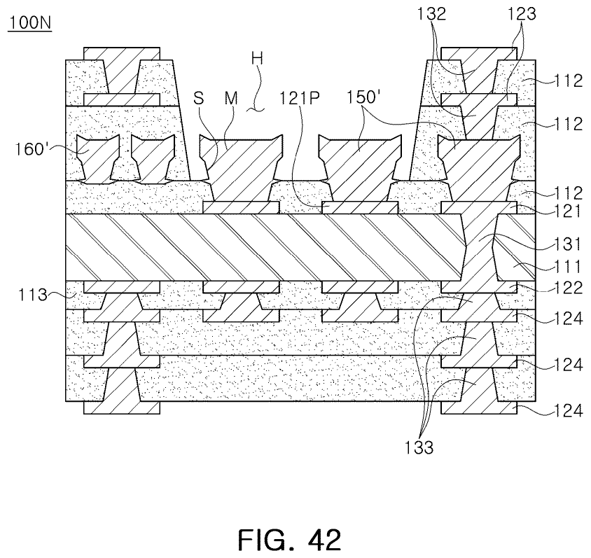

FIG. 42 is a schematic cross-sectional view of another example embodiment of a printed circuit board.

Referring to FIG. 42, a printed circuit board 100N according to another example may have a structure in which a metal post 150′, a first metal pattern 160′, and the like are applied to a multilayer cavity substrate including a plurality of insulating layers 111, 112, and 113, a plurality of wiring layers 121, 122, 123, and 124, and a plurality of via layers 131, 132, and 133. For example, the printed circuit board 100N according to another example may have a blind-shaped cavity H penetrating a portion of a plurality of first build-up insulating layers 112 among the plurality of insulating layers 111, 112, and 113. A metal post 150′ may be disposed on the cavity H, and at least a portion of the metal post 150′ may be exposed through the cavity H. For example, a first core wiring layer 121 at least partially exposed through the cavity H, among the plurality of wiring layers 121, 122, 123, and 124 may include a pad 121P, and a portion of the first build-up insulating layer 112 providing a bottom surface of the cavity H may provide an insulating layer 112. A metal post 150′ and/or a first metal pattern 160′ may also be disposed inside the plurality of insulating layers 111, 112, and 113, and the upper surfaces of each of the plurality of insulating layers may be disposed on substantially the same level. A structure of the metal post 150′, the first metal pattern 160′, and the like, is not limited to the structure shown in the drawing, and the metal post and/or metal pattern described in the above-described printed circuit boards 100A, 100B, 100C, 100D, 100E, 100F, 100G, 100H, 100I, 100J, 100K, 100L, and 100M may also be applied. The other descriptions may be substantially the same as those described above.

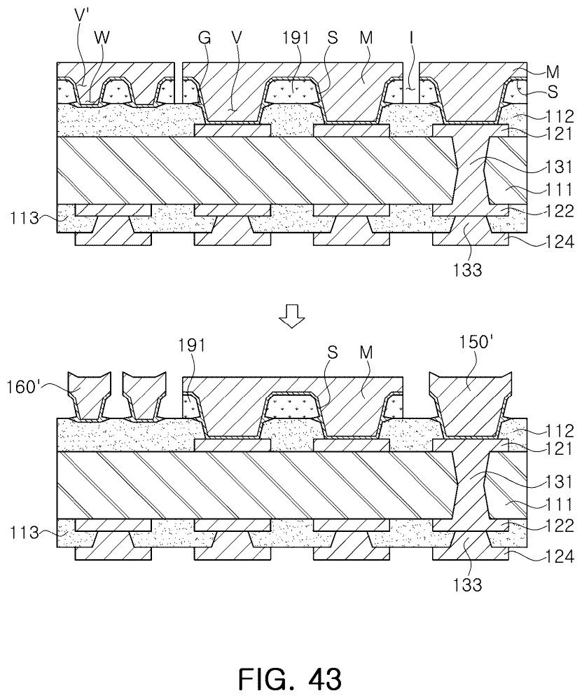

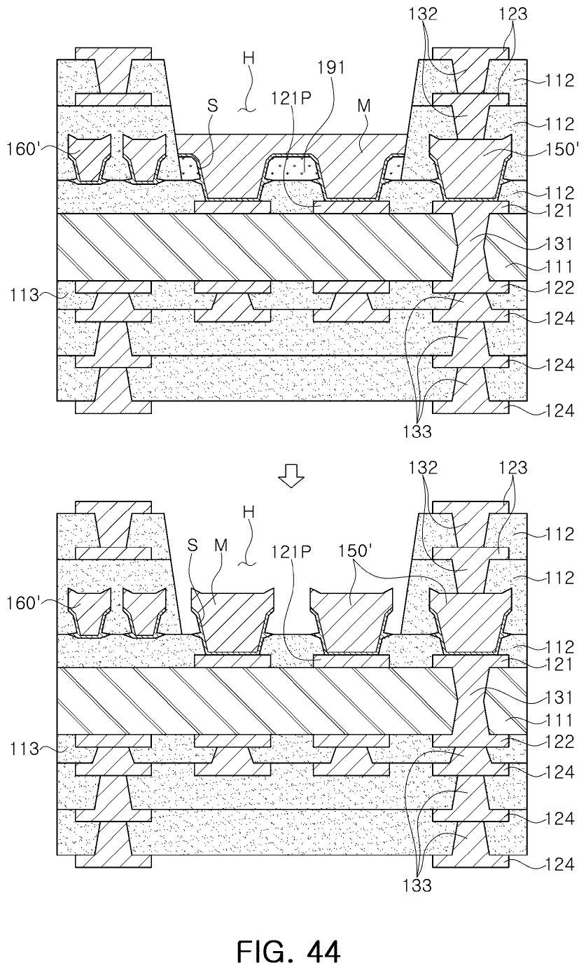

FIGS. 43 and 44 are process diagrams schematically illustrating an example embodiment of manufacturing the metal post of FIG. 42.

First, first and second core wiring layers 121 and 122 and a first via layer 131 may be formed on a core insulating layer 111, first and second build-up insulating layers 112 and 113 may be formed on both surfaces of the core insulating layer 111, and a second build-up wiring layer 124 and a second build-up via layer 133 may be formed in the second build-up insulating layer 113. In addition, a protective layer 191 may be formed on the first build-up insulating layer 112, and a seed layer S and a metal layer M may be formed after processing a via portion V, another via portion V′, a gap portion G, a groove portion W, and the like. Thereafter, a line (1) for forming a cavity H may be processed. Next, a portion of each of the seed layer S and the metal layer M in the remaining region except for a region in which the cavity H is to be formed may be removed. For example, a portion of each of the seed layer S and the metal layer M may be peeled from the protective layer 191. Thereafter, the protective layer 191 of the remaining region except for the region in which the cavity H is to be formed may be removed. Next, first and second build-up insulating layers 112 and 113, first and second build-up wiring layers 123 and 124, and first and second build-up via layers 132 and 133 may be formed in the required number of layers through a build-up process. Thereafter, a cavity H penetrating a portion of the first build-up insulation layer 112 may be processed. For example, laser processing or blast processing can be used, and the metal layer M may be used as a stopper. Next, a portion of each of the seed layer S and the metal layer M in the cavity H region may be removed. For example, a portion of each of the seed layer S and the metal layer M may be peeled from a protective layer 191. Thereafter, the protective layer 191 in the cavity H region may be removed. Through a series of processes, a multilayer cavity substrate to which a metal post 150′, a first metal pattern 160′, or the like, are applied may be formed, and the other descriptions may be substantially the same as those described above.

In the example embodiments, a virtual line may be a virtual line that does not actually have a thickness in cross-section, and may be a reference line for defining a positional relationship of components only. For example, components disposed above and components disposed below the virtual line may be directly connected to each other as needed, and may be integrated with each other without a boundary.

In the example embodiments, the term “covering” may include a case of covering at least partially as well as a case of covering completely, and may also include a case of covering not only directly but also indirectly. In addition, the term “filling” may include a case of completely filling but also a case of at least partially filling, and may also include a case of approximately filling. For example, the term “filling” may include a case in which, for example, some pores or voids exist. Also, the term “surrounding” may include not only a case of completely surrounding but also a case of partially surrounding, and a case of approximately surrounding. Also, the term “exposing” may include exposing partially as well as exposing completely, and “exposing” may refer to exposing from embedding a corresponding component. For example, exposing a pad by an opening may be exposing the pad from a resist layer, and a surface treatment layer or the like may be further disposed on the exposed pad.

In the example embodiments, determination may be performed by including process errors, positional deviations, errors at the time of measurement, which may occur substantially in a manufacturing process. For example, being disposed on substantially the same level may include not only a case of being disposed in completely the same position, but also a case of being disposed in approximately the same position. Also, being substantially tapered may include not only a completely tapered shape but also an approximately tapered shape, for example, it may be determined by the overall shape.

In the example embodiments, the same insulating material may refer to not only the same insulating material but also the same type of insulating material. Accordingly, the composition of the insulating material may be substantially the same, but the specific composition ratio thereof may be slightly different.

In the example embodiment, the meaning on a cross-section may mean a cross-sectional shape when an object is vertically cut, or a cross-sectional shape when the object is viewed from the side. Also, the meaning on a plane may refer to a planar shape when the object is horizontally cut, or a planar shape when the object is viewed from the top or the bottom.

In the example embodiments, the terms “a lower side, a lower portion, a lower surface, the other surface”, and the like, are used to refer to a downward direction based on the cross-section of the drawing for convenience, and the terms “an upper side, an upper portion, an upper surface, one surface”, and the like, are used as the opposite directions. However, this is a definition of direction for the convenience of explanation, and the scope of the claim is not specifically limited by the description of this direction, and the concept of upper/lower may be changed at any time.

In the example embodiments, the term “connected” may not only refer to “directly connected” but also include “indirectly connected” by may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from another, and may not limit a sequence and/or an importance, or others, in relation to the elements. In some cases, a first element may be referred to as a second element, and similarly, a second element may be referred to as a first element without departing from the scope of right of the example embodiments.

In the example embodiments, a thickness, a width, a length, a depth, a line width, a gap, a pitch, a separation distance, surface roughness, and the like, may be measured using a scanning microscope, an optical microscope, or the like, based on a cross-section a printed circuit board that has been polished or cut, respectively. The cut cross-section may be a vertical cross-section or a horizontal cross-section, and each value may be measured based on a required cut cross-section. For example, the width of the upper and/or lower portions of a via may be measured on a cross-section cut along the central axis of the via. In this case, when the value is not constant, the value may be determined as an average value of values measured at five arbitrary points.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as being relevant to the other example embodiment unless otherwise indicated.

The terms used herein describe particular embodiments only, and the present disclosure is not limited thereby. As used herein, the singular forms “a,” “an,” and “the” are intended to include the plural forms as well, unless the context clearly indicates otherwise.

As set forth above, according to one of the effects of the present disclosure, a printed circuit board including a metal post having substantially no plating deviation and secured flatness and a method for manufacturing the same, may be provided.

As another effect of the present disclosure, a printed circuit board including a metal post having excellent reliability and a method for manufacturing the same, may be provided.

As another effect of the present disclosure, a printed circuit board for cost reductions and process simplification and a method for manufacturing the same, may be provided.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a metal post; and
an insulating layer covering at least a portion of the metal post,
wherein, based on a virtual line on substantially the same level as an uppermost surface of the insulating layer,
the metal post includes a first conductive portion disposed below the virtual line, a second conductive portion disposed above the virtual line, and a third conductive portion, at least a portion of the third conductive portion protruding from a side surface of the first conductive portion below the virtual line.

2. The printed circuit board of claim 1, wherein at least another portion of the third conductive portion protrudes from a side surface of the second conductive portion above the virtual line.

3. The printed circuit board of claim 2, wherein the at least portion and the at least another portion of the third conductive portion have a thickness which is substantially smaller toward the outside from side surfaces of each of the first and second conductive portions, respectively.

4. The printed circuit board of claim 2, wherein the third conductive portion surrounds the side surfaces of each of the first and second conductive portions.

5. The printed circuit board of claim 1, wherein an upper surface of the second conductive portion provides an upper surface of the metal post, and
the upper surface of the second conductive portion is substantially flat overall.

6. The printed circuit board of claim 1, wherein an upper surface of the second conductive portion provides an upper surface of the metal post, and
the upper surface of the second conductive portion includes a central region and an edge region surrounding the central region, and at least a portion of the edge region protrudes upwardly from the central region.

7. The printed circuit board of claim 6, wherein the central region is substantially flat, and
the edge region is substantially pointed upwardly.

8. The printed circuit board of claim 1, wherein the upper surface of the second conductive portion includes a central region and an edge region surrounding the central region, and
based on the virtual line, a maximum height of the central region is smaller than a maximum height of the edge region.

9. The printed circuit board of claim 1, wherein the side surfaces of each of the first and second conductive portions include a tapered region.

10. The printed circuit board of claim 9, wherein the side surface of the second conductive portion includes a plurality of regions with different inclinations.

11. The printed circuit board of claim 10, wherein the side surface of the second conductive portion has a step structure.

12. The printed circuit board of claim 1, further comprising:
a surface treatment layer covering an upper surface of the metal post,
wherein the surface treatment layer includes at least one of a tin (Sn) layer and a gold (Au) layer.

13. The printed circuit board of claim 1, wherein a plurality of the metal posts are disposed, and
upper surfaces of the plurality of metal posts are disposed on substantially the same level.

14. The printed circuit board of claim 1, wherein a plurality of the metal posts are disposed, and
at least one of the plurality of metal posts has a maximum width in cross-section greater than at least another of the plurality of metal posts.

15. The printed circuit board of claim 1, wherein a plurality of the metal posts are disposed, and
an upper surface of at least one of the plurality of metal posts is disposed above an upper surface of at least another of the plurality of metal posts.

16. The printed circuit board of claim 1, wherein the insulating layer includes a first insulating material and a second insulating material disposed on the first insulating material,
based on another virtual line on substantially the same level as at an interface between the first and second insulating materials,
the metal post further includes another third conductive portion, at least a portion of the third conductive portion protruding from a side surface of the first conductive portion below the another virtual line, and
at least another portion of the third conductive portion protrudes from the side surface of the first conductive portion above the virtual line.

17. The printed circuit board of claim 1, further comprising:
a pad,
wherein the insulating layer covers a portion of the pad, and
the metal post is connected to an upper surface of the pad exposed from the insulating layer.

18. The printed circuit board of claim 17, further comprising:
a plurality of insulating layers;
a plurality of wiring layers respectively disposed on or within the plurality of insulating layers; and
a plurality of via layers respectively penetrating at least a portion of at least one of the plurality of insulating layers,
a wiring layer disposed on an uppermost side of the plurality of wiring layers includes the pad, and
the insulating layer is an insulating layer disposed on an uppermost side of the plurality of insulating layers.

19. The printed circuit board of claim 17, further comprising:
a plurality of insulating layers;
a plurality of wiring layers respectively disposed on or within the plurality of insulating layers; and
a plurality of via layers respectively penetrating at least a portion of at least one of the plurality of insulating layers,
wherein the plurality of insulating layers have a cavity exposing at least a portion of at least one of the plurality of wiring layers,
the wiring layer exposed through the cavity includes the pad,
the insulating layer providing a bottom surface of the cavity, and
at least a portion of the metal post is exposed through the cavity.

20. The printed circuit board of claim 1, further comprising:
a metal pattern,
wherein the insulating layer covers at least a portion of the metal pattern,
the metal pattern includes a fourth conductive portion disposed below the virtual line and thinner than the first conductive portion, a fifth conductive portion disposed above the virtual line, and a sixth conductive portion, at least a portion of the sixth conductive portion protruding from a side surface of the fourth conductive portion below the virtual line, and
at least another portion of the sixth conductive portion protrudes from a side surface of the fifth conductive above the virtual line.

21. The printed circuit board of claim 20, wherein an upper surface of the metal post and an upper surface of the metal pattern are disposed on substantially the same level as each other, and
a lower surface of the metal pattern is disposed above a lower surface of the metal post.

22. The printed circuit board of claim 1, wherein the metal post includes a metal layer and a seed layer covering at least a portion of each of a lower surface and a side surface of the metal layer, and
each of the first to third conductive portions includes at least one of the metal layer and the seed layer.

23. The printed circuit board of claim 22, wherein the seed layer is in contact with a side surface of a region of the metal layer disposed above the virtual line, but is spaced apart from the upper surface of the metal layer.

24. The printed circuit board of claim 23, wherein the seed layer is in contact with a portion of the side surface of the region of the metal layer disposed above the virtual line, but is spaced apart from another portion of the side surface of the region of the metal layer disposed above the virtual line.

25. A method for manufacturing a printed circuit board, comprising:
preparing a substrate including an insulating layer and a protective layer disposed on the insulating layer;
forming a via portion penetrating the protective layer in a thickness direction from an upper surface of the protective layer and further penetrating at least a portion of the insulating layer;
forming a gap portion penetrating a portion of each of the insulating layer and the protective layer in a direction substantially perpendicular to the thickness direction from a side portion of the via portion at an interface between the insulating layer and the protective layer;
forming a seed layer disposed on a bottom surface of the via portion, a wall surface of the via portion, and an upper surface of the protective layer, and filling at least a portion of the gap portion;
forming a metal layer disposed on the seed layer, and filling at least a portion of the via portion;
removing a portion of each of the seed layer and the metal layer, to expose at least a portion of the upper surface of the protective layer; and
removing the protective layer.

26. The method for manufacturing a printed circuit board of claim 25, wherein the forming the gap portion includes a desmearing treatment.

27. The method for manufacturing a printed circuit board of claim 25, wherein the removing a portion of each of the seed layer and the metal layer includes removing a portion of each of the seed layer and the metal layer by etching, and
the removing a portion of each of the seed layer and the metal layer by etching is performed so that an upper surface of the metal layer and an upper surface of the protective layer are substantially coplanar with each other.

28. The method for manufacturing a printed circuit board of claim 25, wherein the removing a portion of each of the seed layer and the metal layer includes peeling a portion of each of the seed layer and the metal layer from the protective layer, and
based on one virtual line on substantially the same level as an uppermost surface of the protective layer,
in the peeling a portion of each of the seed layer and the metal layer from the protective layer, another portion of the metal layer remains above the one virtual line.

29. The method for manufacturing a printed circuit board of claim 28, wherein in the peeling a portion of each of the seed layer and the metal layer from the protective layer, at least a portion of an edge region surrounding a central region of the upper surface of the metal layer protrudes upwardly from the central region.

30. A printed circuit board, comprising:
a metal post; and
an insulating layer covering at least a portion of the metal post,
wherein the metal post includes a lower portion disposed in the insulating layer, an upper portion protruding on the insulating layer, and a protruding portion protruding from a side surface of one of the lower portion and the upper portion of the metal post, and
the protruding portion includes a lower surface extending towards the lower portion in a direction inclined with respect to an upper surface of the insulating layer.

31. The printed circuit board of claim 30, wherein the protruding portion has a thickness decreasing in a direction away from the side surface of the upper portion.

32. The printed circuit board of claim 30, wherein the protruding portion surrounds the side surface of the upper portion.

33. The printed circuit board of claim 30, wherein the side surfaces of the upper and lower portions include a tapered region.

34. The printed circuit board of claim 30, further comprising:
a surface treatment layer covering an upper surface of the metal post,
wherein the surface treatment layer includes at least one of a tin (Sn) layer and a gold (Au) layer.

35. The printed circuit board of claim 30, wherein the metal post includes a metal layer and a seed layer covering at least a portion of each of a lower surface and a side surface of the metal layer, and
each of the lower portion, the upper portion, and the protruding portion includes at least one of the metal layer and the seed layer.

36. The printed circuit board of claim 35, wherein an upper surface of the metal post is an upper surface of the metal layer.

37. The printed circuit board of claim 30, wherein an upper surface of the upper portion provides an upper surface of the metal post, and
the upper surface of the upper portion includes a central region and an edge region surrounding the central region, and at least a portion of the edge region protrudes upwardly from the central region.
